(19) United States
(12) Patent Application Publication
(10) Pub. No.: US 2026/0349302 A1
(43) Pub. Date: Nov. 5, 2026

(54) ARRAY SUBSTRATE AND DISPLAY DEVICE

(71) Applicants: Hefei Xinsheng Optoelectronics Technology Co., Ltd., Hefei, Anhui (CN); BOE Technology Group Co., Ltd., Beijing (CN)

(72) Inventors: Dongdong ZHANG, Beijing (CN); Peng CHEN, Beijing (CN); Fengzhen LV, Beijing (CN); Huakun DU, Beijing (CN); Jingpeng WANG, Beijing (CN); Long LI, Beijing (CN); Li MA, Beijing (CN); Xueyan SONG, Beijing (CN); Yunhua FANG, Beijing (CN); Tao LI, Beijing (CN); Chang CHENG, Beijing (CN)

(21) Appl. No.: 19/488,600

(22) PCT Filed: May 27, 2024
(86) PCT No.: PCT/CN2024/095422

§ 371 Date: Nov. 27, 2025

(30) Foreign Application Priority Data
Jun. 12, 2023 (CN) 202310698843.2

(51) Int. Cl. G02F 1/1362; G09G 3/36

(52) U.S. Cl. CPC G02F 1/136286; G02F 1/136204; G09G 3/3677; G09G 2300/0426; G09G 2330/04

(57) ABSTRACT

An array substrate, comprising: a base, multiple scanning lines provided on the base, at least one dummy wire, and a scanning drive circuit. The multiple scanning lines are in a display area and extend in a first direction. The at least one dummy wire is in a frame region and extends in a second direction. The scanning drive circuit is in the frame region. At least one scanning line comprises a scanning connection end and an extension end which extend to the frame region, and the scanning connection end is electrically connected to the scanning drive circuit. The at least one dummy wire is disconnected at the extension end of at least one scanning line, so that the orthographic projection of the at least one dummy wire on the base does not overlap the orthographic projection of the extension end of the at least one scanning line on the base.

### CROSS-REFERENCE TO RELATED APPLICATIONS

The present application is a U.S. National Phase Entry of International Application PCT/CN2024/095422 having an international filing date of May 27, 2024, which claims the priority to Chinese Patent Application No. 202310698843.2, filed to the CNIPA on Jun. 12, 2023 and entitled “Array Substrate and Display Device”, contents of the above-identified applications should be construed as being incorporated into the present application by reference.

### TECHNICAL FIELD

The present disclosure relates to, but is not limited to, the field of display technologies, in particular to a display substrate and a display apparatus.

### BACKGROUND

Touch and Display Driver Integration (TDDI) products have gradually become a mainstream touch technology due to their advantages such as thinness, high integration, and high performance. In the field of mobile and touch display products, a TDDI technology has been basically adopted at present.

### SUMMARY

The following is a summary of subject matters described herein in detail. The summary is not intended to limit the protection scope of claims.

Embodiments of the present disclosure provide an array substrate and a display apparatus.

In one aspect, an embodiment of the present disclosure provides an array substrate including a base substrate, a plurality of scanning lines disposed on the base substrate, at least one dummy wire, and a scanning drive circuit. The base substrate includes a display area and a bezel area located around the display area. The plurality of scanning lines are located at least in the display area and extend along a first direction. The at least one dummy wire is located in the bezel area and extends along a second direction. The scanning drive circuit is located in the bezel area. At least one scanning line includes a scanning connection end and an extension end which extend to the bezel area, and the scanning connection end is electrically connected to the scanning drive circuit. The at least one dummy wire is disconnected at the extension end of the at least one scanning line, so that an orthographic projection of the at least one dummy wire on the base substrate is not overlapped with an orthographic projection of the extension end of the at least one scanning line on the base substrate. The second direction intersects with the first direction.

In some exemplary implementation modes, the at least one dummy wire includes a plurality of dummy wire segments arranged sequentially along the second direction, a first fracture is disposed between adjacent dummy wire segments in the second direction, a length of the first fracture along the second direction is greater than a length of the extension end of the at least one scanning line along the second direction.

In some exemplary implementation modes, the array substrate further includes: a first common voltage signal line and a second common voltage signal line located in the bezel area; the first common voltage signal line is electrically connected with the second common voltage signal line, the first common voltage signal line is located at a side of the second common voltage signal line away from the base substrate, and orthographic projections of the first common voltage signal line and the second common voltage signal line on the base substrate are at least partially overlapped.

In some exemplary implementation modes, at least one dummy wire segment of the at least one dummy wire is electrically connected with at least one of the second common voltage signal line and the first common voltage signal line.

In some exemplary implementation modes, the array substrate further includes a plurality of first connection lines located in the bezel area. The scanning connection end of the at least one scanning line is electrically connected with the scanning drive circuit through a first connection line of the plurality of first connection lines; the first connection line is located at a side of the scanning line away from the base substrate.

In some exemplary implementation modes, the array substrate further includes a plurality of first connection electrodes located in the bezel area. The scanning connection end of the scanning line is electrically connected with the first connection line through a first connection electrode of the plurality of first connection electrodes, and the first connection electrode is located at a side of the first connection line away from the base substrate.

In some exemplary implementation modes, the first connection electrode and the first common voltage signal line are disposed in a same layer, the first common voltage signal line has a plurality of first hollow portions, and an orthographic projection of the first connection electrode on the base substrate is located within a first hollow portion of the plurality of first hollow portions.

In some exemplary implementation modes, the array substrate further includes a first voltage line located in the bezel area, and a plurality of second connection lines. The first voltage line is located at a side of the first common voltage signal line and the second common voltage signal line away from the display area, and is located at a side of the scanning drive circuit close to the display area. The first voltage line is electrically connected with the scanning drive circuit through a second connection line of the plurality of second connection lines, and the first voltage line is configured to provide a first voltage signal to the scanning drive circuit.

In some exemplary implementation modes, the bezel area includes at least: a left bezel region and a right bezel region located at two sides of the display area along the first direction; the scanning drive circuit includes a first drive circuit located in the left bezel region and a second drive circuit located in the right bezel region; the first drive circuit includes a plurality of cascaded first drive units, and the second drive circuit includes a plurality of cascaded second drive units. In the left bezel region, a (2a−1)-th-stage first drive unit and a (2a)-th-stage first drive unit of the first drive circuit are electrically connected with the first voltage line through a same second connection line. In the right bezel region, a (2b−1)-th-stage second drive unit and a (2b)-th-stage second drive unit of the second drive circuit are electrically connected with the first voltage line through a same second connection line; a and b are integers greater than 0.

In some exemplary implementation modes, the array substrate further includes: a plurality of second connection electrodes located in the bezel area, wherein the first voltage line is electrically connected with the second connection line through a second connection electrodes of the plurality of second connection electrodes; the second connection electrode is located at a side of the first voltage line and the second connection line away from the base substrate, and the second connection electrode and the first common voltage signal line are disposed in a same layer. An edge of the first common voltage signal line away from the display area has a plurality of notches, at least one of the notches is configured to accommodate one of the second connection electrodes, and an orthographic projection of the at least one notch on the base substrate covers an orthographic projection of the second connection electrode on the base substrate in the first direction.

In some exemplary implementation modes, the plurality of notches and extending ends of the plurality of scanning lines are disposed at intervals along the second direction.

In some exemplary implementation modes, the bezel area includes at least a left bezel region and a right bezel region located at two sides of the display area along the first direction. Both the left bezel region and the right bezel region are provided with at least one dummy wire.

In some exemplary implementation modes, the bezel area includes at least: a left bezel region and a right bezel region located at two sides of the display area along the first direction; in the left bezel region or the right bezel region, scanning connection ends and extension ends of the plurality of scanning lines are arranged at intervals along the second direction.

In some exemplary implementation modes, the array substrate further includes a plurality of sub-pixels located in the display area, the plurality of sub-pixels are arranged in a plurality of rows, and each row of sub-pixels includes a plurality of sub-pixels arranged along the first direction. The scanning drive circuit includes a first drive circuit located in the left bezel region and a second drive circuit located in the right bezel region. A scanning connection end of at least one scanning line extending to the left bezel region is electrically connected with the first drive circuit; the first drive circuit is configured to provide a data signal to a (2i−1)-th row of sub-pixels of the display area. A scanning connection end of at least one scanning line extending to the right bezel region is electrically connected with the second drive circuit; the second drive circuit is configured to provide a scanning signal to a (2i)-th row of sub-pixels of the display area; i is an integer greater than 0.

In some exemplary implementation modes, the bezel area further includes a lower bezel region located at a side of the display area along the second direction. The array substrate further includes: a plurality of auxiliary scanning lines located in the lower bezel region and extending along the first direction, a plurality of first auxiliary drive units located in the left bezel region, and a plurality of second auxiliary drive units located in the right bezel region. At least one of the plurality of auxiliary scanning lines includes: an auxiliary scanning connection end extending to the left bezel region and an auxiliary extension end extending to the right bezel region; or, an auxiliary scanning connection end extending to the right bezel region and an auxiliary extension end extending to the left bezel region. The auxiliary scanning connection end of the at least one auxiliary scanning line is electrically connected with a first auxiliary drive unit of the plurality of first auxiliary drive units or a second auxiliary drive unit of the plurality of second auxiliary drive units. In the left bezel region or the right bezel region, auxiliary scanning connection ends and auxiliary extension ends of the plurality of auxiliary scanning lines are disposed at intervals along the second direction.

In some exemplary implementation modes, the plurality of first auxiliary drive units are configured to provide a reset signal to the first drive circuit; the plurality of second auxiliary drive units are configured to provide a reset signal to the second drive circuit.

In some exemplary implementation modes, the at least one dummy wire bypasses an extension end of at least one scanning line from a side away from the display area.

In another aspect, an embodiment of the present disclosure also provides a display apparatus, including the array substrate as described above.

Other aspects of the present disclosure may be comprehended after drawings and detailed description are read and understood.

### BRIEF DESCRIPTION OF DRAWINGS

Accompanying drawings are used to provide an understanding of technical solutions of the present disclosure, and form a part of the specification. The accompanying drawings and embodiments of the present disclosure are adopted to explain the technical solutions of the present disclosure, and do not form limitations on the technical solutions of the present disclosure.

FIG. 1 is a schematic diagram of an array substrate according to at least one embodiment of the present disclosure.

FIG. 2 is a schematic diagram of a touch control structure of an array substrate according to at least one embodiment of the present disclosure.

FIG. 3 is a schematic diagram of a partial structure of a display area of an array substrate according to at least one embodiment of the present disclosure.

FIG. 4 is a schematic diagram of a scanning drive circuit according to at least one embodiment of the present disclosure.

FIG. 5 is a schematic diagram of a partial film layer in FIG. 1.

FIG. 6A is a partial plan schematic view of a boundary region between a display area and a right bezel region according to at least one embodiment of the present disclosure.

FIG. 6B is a partial plan schematic view of a right bezel region according to at least one embodiment of the present disclosure.

FIG. 7A is a schematic partial sectional view along a Q-Q′ direction in FIG. 6A.

FIG. 7B is a schematic partial sectional view along an R-R′ direction in FIG. 6A.

FIG. 8A is a schematic plan view of an array substrate after a first conductive layer is formed in FIG. 6A.

FIG. 8B is a schematic plan view of an array substrate after a first conductive layer is formed in FIG. 6B.

FIG. 9A is a schematic plan view of the array substrate after a semiconductor layer is formed in FIG. 6A.

FIG. 9B is a schematic plan view of the array substrate after a semiconductor layer is formed in FIG. 6B.

FIG. 10A is a schematic plan view of the array substrate after a second conductive layer is formed in FIG. 6A.

FIG. 10B is a schematic plan view of the array substrate after a second conductive layer is formed in FIG. 6B.

FIG. 11A is a schematic diagram of the second conductive layer in FIG. 10A.

FIG. 11B is a schematic diagram of the second conductive layer in FIG. 10B.

FIG. 12 is a schematic plan view of the array substrate after a third insulation layer is formed in FIG. 6A.

FIG. 13 is a schematic plan view of the array substrate after a first transparent conductive layer is formed in FIG. 6A.

FIG. 14A is a schematic plan view of the array substrate after a fourth insulation layer is formed in FIG. 6A.

FIG. 14B is a schematic plan view of the array substrate after a fourth insulation layer is formed in FIG. 6B.

FIG. 15A is a schematic diagram of a second transparent conductive layer in FIG. 6A.

FIG. 15B is a schematic diagram of a second transparent conductive layer in FIG. 6B.

FIG. 16 is a schematic diagram of a partial region in FIG. 6A.

FIG. 17 is another schematic diagram of a scanning drive circuit according to at least one embodiment of the present disclosure.

FIG. 18 is a schematic plan view of a lower right corner of an array substrate according to at least one embodiment of the present disclosure.

FIG. 19A is a schematic diagram of the array substrate after a first conductive layer is formed in FIG. 18.

FIG. 19B is a schematic diagram of the array substrate after a semiconductor layer is formed in FIG. 18.

FIG. 19C is a schematic diagram of the array substrate after a second conductive layer is formed in FIG. 18.

FIG. 19D is a schematic diagram of the second conductive layer in FIG. 19C.

FIG. 19E is a schematic diagram of the array substrate after a fourth insulation layer is formed in FIG. 18.

FIG. 19F is a schematic diagram of a second transparent conductive layer in FIG. 18.

FIG. 20 is another schematic diagram of an array substrate according to at least one embodiment of the present disclosure.

FIG. 21 is a schematic diagram of a partial film layer of FIG. 20.

FIG. 22 is another schematic diagram of an array substrate according to at least one embodiment of the present disclosure.

### DETAILED DESCRIPTION

The embodiments of the present disclosure will be described below with reference to the drawings in detail. Implementation modes may be implemented in multiple different forms. Those of ordinary skills in the art can easily understand such a fact that modes and contents may be transformed into one or more forms without departing from the purpose and scope of the present disclosure. Therefore, the present disclosure should not be explained as being limited to the contents recorded in the following implementation modes only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one mode of the present disclosure is not necessarily limited to the dimensions, and shapes and sizes of a plurality of components in the drawings do not reflect actual scales. In addition, the accompanying drawings schematically illustrate ideal examples, and one mode of the present disclosure is not limited to shapes, numerical values, or the like shown in the drawings.

Ordinal numerals such as “first”, “second” and “third” in the present disclosure are set to avoid confusion between constituent elements, but not intended for restriction in quantity. “A plurality of” in the present disclosure means two or more in quantity.

In the present disclosure, for convenience, wordings indicating orientation or positional relationship such as “middle”, “upper”, “lower”, “front”, “rear”, “vertical”, “horizontal”, “top”, “bottom”, “inner” and “outer” are employed to explain positional relationship between the constituent elements with reference to the drawings, they are employed for ease of description of the specification and simplification of the description only, but do not indicate or imply that the referred device or element must have a particular orientation, or is constructed and operated in a particular orientation, and therefore cannot be construed as limitations on the present disclosure. The positional relationships between the constituent elements are changed as appropriate based on directions according to which the constituent elements are described. Therefore, appropriate replacements based on situations are allowed, which is not limited to the expressions in the specification.

In the present disclosure, the terms “mounting”, “coupling” and “connection” are to be understood broadly, unless otherwise expressly specified and defined. For example, a connection may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand meanings of the aforementioned terms in the present disclosure according to situations.

In the present disclosure, a transistor refers to an element at least including three terminals, i.e., a gate (gate electrode), a drain electrode, and a source electrode. The transistor has a channel region between the drain electrode (drain electrode terminal, drain electrode region, or drain electrode) and the source electrode (source electrode terminal, source electrode region, or source electrode), and a current can flow through the drain electrode, the channel region, and the source electrode. In the present disclosure, the channel region refers to a region through which a current mainly flows.

In the present disclosure, to distinguish two electrodes of a transistor except the gate electrode, one of the electrodes is referred to as a first electrode and the other electrode is referred to as a second electrode. The first electrode may be a source electrode or a drain electrode, and the second electrode may be a drain electrode or a source electrode. In addition, the gate electrode of the transistor may be referred to as a control electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the present disclosure.

In the present disclosure, “electric connection” includes a case where constituent elements are connected through an element with a certain electrical effect. The “element with a certain electrical effect” is not particularly limited as long as electrical signals between the connected constituent elements can be transmitted. Examples of the “element with a certain electrical effect” not only include electrodes and wirings, but also include switching elements such as transistors, resistors, inductors, capacitors, other elements with one or more functions, and the like.

In the present disclosure, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the present disclosure, “about” and “substantially” means that a boundary is not defined strictly and a case within a range of process and measurement errors is allowed.

In some implementation modes, an array substrate may include a plurality of scanning lines extending along a first direction and a plurality of data lines extending along a second direction located in a display area. The plurality of data lines and the plurality of scanning lines may intersect to form a plurality of sub-pixel regions. A dummy wire may be disposed in a bezel area of the array substrate to ensure process uniformity. There is Electro-Static Discharge (ESD) in a preparation process of the array substrate. An extension end of a scanning line is not electrically connected, and electrostatic electricity will be released at the extension end of the scanning line. Since the scanning line and the dummy wire are located in different film layers, and their extension directions intersect, electrostatic electricity released at an extension end of the scanning line breaks through an insulation layer between the scanning line and the dummy wire, causing a short circuit between the scanning line and the dummy wire. The short circuit between the scanning line and the dummy wire will affect stability of a scanning signal transmitted by the scanning line adversely. For example, the dummy wire transmits a common voltage signal, after the short circuit, the scanning signal will be pulled down, causing the scanning signal to be abnormal, resulting in poor functionality like horizontal stripes, thus affecting a display effect adversely.

An embodiment provides an array substrate including a base substrate, a plurality of scanning lines, at least one dummy wire, and a scanning drive circuit. The base substrate includes a display area and a bezel area located around the display area. The plurality of scanning lines are located at least in the display area and extend along a first direction. The at least one dummy wire is located in the bezel area and extends along a second direction. The second direction intersects with the first direction, for example, the second direction may be perpendicular to the first direction. The scanning drive circuit is located in the bezel area. At least one scanning line includes a scanning connection end and an extension end which extend to the bezel area, and the scanning connection end is electrically connected with the scanning drive circuit. The at least one dummy wire is disconnected at the extension end of the at least one scanning line, so that an orthographic projection of the at least one dummy wire on the base substrate is not overlapped with an orthographic projection of the extension end of the at least one scanning line on the base substrate.

In the array substrate provided by the present embodiment, by providing a dummy wire to be disconnected at an extension end of a scanning line, it is possible to avoid intersection of the dummy wire with the extension end of the scanning line, thereby reducing a risk of a short circuit between the scanning line and the dummy wires caused by electrostatic discharge at the extension end of the scanning line, and further improving poor horizontal stripes-type functional display.

In some exemplary implementation modes, the at least one dummy wire may include a plurality of dummy wire segments sequentially arranged along the second direction, a first fracture is disposed between adjacent dummy wire segments in the second direction, and a length of the first fracture along the second direction may be greater than a length of the extension end of the at least one scanning line along the second direction. For example, the first fracture may be correspondingly inserted with an extension end of one scanning line. In this example, by breaking the dummy wire to form the first fracture, it is possible to avoid intersection of the dummy wire and the extension end of the scanning line.

In some exemplary implementation modes, the array substrate may further include a first common voltage signal line and a second common voltage signal line located in the bezel area. The first common voltage signal line is electrically connected with the second common voltage signal line, the first common voltage signal line may be located at a side of the second common voltage signal line away from the base substrate, and orthographic projections of the first common voltage signal line and the second common voltage signal line on the base substrate are at least partially overlapped. In some examples, at least one dummy wire segment of the at least one dummy wire is electrically connected with at least one of the second common voltage signal line and the first common voltage signal line. For example, at least one dummy wire segment of the dummy wire may be electrically connected with the second common voltage signal line and the first common voltage signal line, or at least one dummy wire segment of the dummy wire may be electrically connected with the first common voltage signal line, or at least one dummy wire segment of the dummy wire may be electrically connected with the second common voltage signal line. In some examples, all dummy wire segments of the dummy wire may be electrically connected with the first common voltage signal line or with the second common voltage signal line; or, one part of the dummy wire segments may be electrically connected with the first common voltage signal line, and the other part of the dummy wire segments may be electrically connected with the second common voltage signal line. The present embodiment is not limited thereto. In this embodiment, the dummy wire is provided to be electrically connected with the first common voltage signal line or the second common voltage signal line to realize transmission of a common voltage, and an influence of floating connection of the dummy wire on surrounding structures may be avoided.

Solutions of the embodiment will be described below through a plurality of examples.

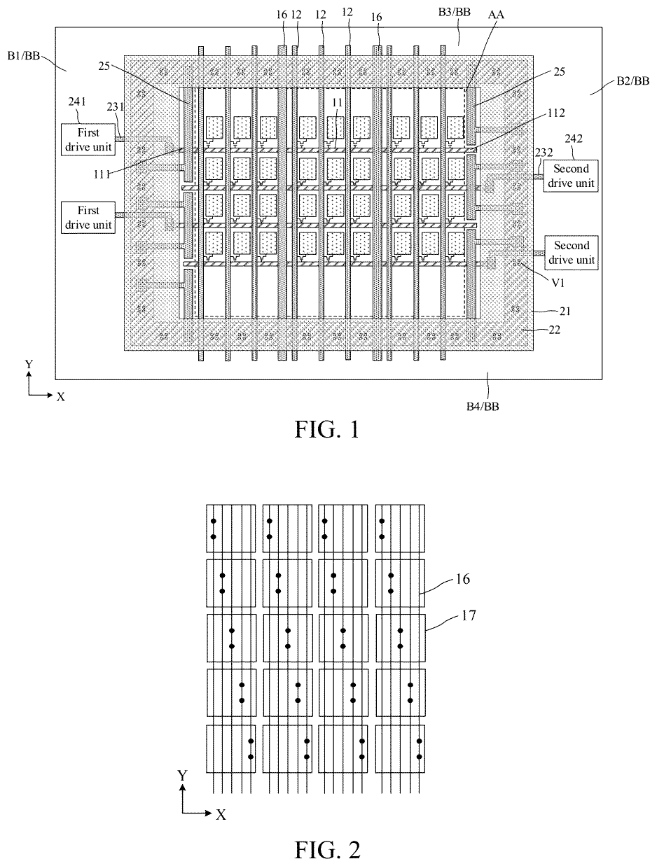

FIG. 1 is a schematic diagram of an array substrate according to at least one embodiment of the present disclosure. In FIG. 1, only partial structures of the display area and the bezel area are briefly illustrated. In some examples, as shown in FIG. 1, the array substrate of this example may include a display area AA and a bezel area BB surrounding a periphery of the display area AA. The bezel area BB may surround the display area AA. In some examples, the display area AA may be rectangular, and the bezel area BB may have a rectangular ring shape. However, the present embodiment is not limited thereto. In other examples, the display area AA may have other shapes.

In some examples, as shown in FIG. 1, the bezel area BB may include a left bezel region B1, a right bezel region B2, an upper bezel area B3, and a lower bezel region B4. The left bezel region B1 and the right bezel region B2 may be located at two sides of the display area AA along a first direction X, and the upper bezel area B3 and the lower bezel region B4 may be located at two sides of the display area AA along a second direction Y. Herein, the first direction X intersects with the second direction Y, for example, the first direction X may be perpendicular to the second direction Y. The left bezel region B1 may be in communication with the upper bezel area B3 and the lower bezel region B4, and the right bezel region B2 may be in communication with the upper bezel area B3 and the lower bezel region B4. A communication region between the left bezel region B1 and the upper bezel area B3 may form an upper left corner, a communication region between the right bezel region B2 and the upper bezel area B3 may form an upper right corner, a communication region between the left bezel region B1 and the lower bezel region B4 may form a lower left corner, and a communication region between the right bezel region B2 and the lower bezel region B4 may form a lower right corner.

In some examples, the left bezel region B1 and the right bezel region B2 may be provided with scanning drive circuits. The lower bezel region B4 may be provided with an integrated chip (for example, a TDDI chip).

In some examples, a display apparatus including the array substrate may be a liquid crystal display apparatus, for example, a touch control display apparatus in which a touch control structure is embedded. In some examples, the display apparatus may include the array substrate, an opposite substrate, and a liquid crystal layer disposed between the array substrate and the opposite substrate. In some examples, the touch control display apparatus may be a touch control display apparatus in an Advanced Super Dimension Switch (ADS) type, or may be a touch control display apparatus in a High-Advanced Dimension Switch (HADS) type with a high aperture ratio. The array substrate may include a pixel electrode and a common electrode, and the pixel electrode and the common electrode may generate an electric field for controlling deflection of liquid crystal molecules in the liquid crystal layer. The opposite substrate may include a base substrate, a color film layer, and a black matrix.

FIG. 2 is a schematic diagram of a touch control structure of an array substrate according to at least one embodiment of the present disclosure. In some examples, a self-capacitive touch control technology may be adopted for the array substrate of the present example. As shown in FIG. 2, the touch control structure of the array substrate may include a plurality of touch control sensing blocks (as self-capacitive electrodes) 17 arranged in an array, and a plurality of touch control signal lines 16 electrically connected with the plurality of touch control sensing blocks 17, respectively. Black dots in FIG. 2 represent electrical connections. The plurality of touch control signal lines 16 may extend along the second direction Y and are arranged along the first direction X. Each touch control signal line 16 may be electrically connected with one touch control sensing block 17. In some examples, when touching, a touch object (e.g., a human finger) touches the display apparatus including the array substrate, capacitance of a touch control sensing block 17 located at a touch point changes, and the integrated chip may determine a touch position by detecting self-capacitance change of the touch control sensing block 17.

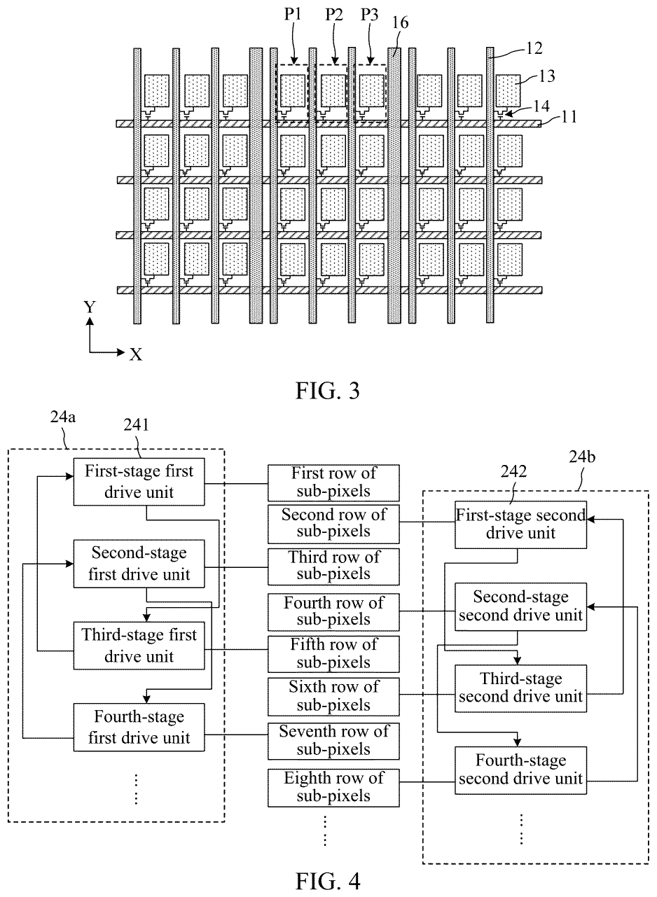

FIG. 3 is a schematic diagram of a partial structure of a display area of an array substrate according to at least one embodiment of the present disclosure. In some examples, as shown in FIGS. 1 and 3, the array substrate of the present example may include at least a base substrate and a plurality of pixel units disposed on the base substrate and located in the display area AA, a plurality of touch control signal lines 16, a plurality of data lines 12, and a plurality of scanning lines 11. The plurality of data lines 12 may extend along the second direction Y and be arranged along the first direction X; the plurality of scanning lines 11 may extend along the first direction X and be sequentially arranged along the second direction Y. The plurality of data lines 12 and the plurality of scanning lines 11 may intersect to form a plurality of sub-pixel regions. For example, regions defined by intersection of adjacent data lines 12 and adjacent scanning lines 11 may be sub-pixel regions. Each sub-pixel region may be provided with one sub-pixel. At least one pixel unit may include three sub-pixels (e.g., including a first sub-pixel P1, a second sub-pixel P2, and a third sub-pixel P3) sequentially arranged along the first direction X. A plurality of sub-pixels of the display area are arranged in a plurality of rows and columns, one row of sub-pixels includes a plurality of sub-pixels arranged along the first direction X, and one column of sub-pixels includes a plurality of sub-pixels arranged along the second direction Y. For example, the first sub-pixel P1, the second sub-pixel P2, and the third sub-pixel P3 may be configured to emit light rays with different colors after being matched with the opposing substrate.

In some examples, a sub-pixel region may include an opening region and a non-opening region surrounding the opening region. In some examples, the non-opening region may be a region that is shielded by the black matrix of the opposing substrate, and the opening region may be a region that is not shielded by the black matrix. For example, adjacent scanning lines 11 and data lines 12 may all be located in the non-opening region. In some examples, the array substrate of the present embodiment is configured to achieve a display function, an opening region of each sub-pixel region may be configured for display, and a non-opening region surrounds the opening region and is not for display. However, the present embodiment is not limited thereto. In some examples, the array substrate may be used for achieving other functions.

In some examples, as shown in FIG. 3, each sub-pixel may include a switching transistor 14, a pixel electrode 13, and a common electrode located within a sub-pixel region. The switching transistor 14 may be located in a non-opening region of the sub-pixel region, for example, at an intersection position of a data line 12 and a scanning line 11. The pixel electrode 13 and the common electrode may be located at least in an opening region of the sub-pixel region. Common electrodes of a plurality of sub-pixels may be of an interconnected integral structure.

In some examples, as shown in FIG. 3, the switching transistor may be a Thin Film Transistor (TFT). The switching element 14 may include a control electrode, an active layer, a first electrode, and a second electrode. The control electrode of the switching transistor 14 may be electrically connected with the scanning line 11, the first electrode may be electrically connected with the data line 12, and the second electrode may be electrically connected with the pixel electrode 13. Under control of the scanning line 11, the switching transistor 14 may supply a data signal transmitted by the data line 12 to the pixel electrode 13.

In some examples, as shown in FIG. 3, one touch control signal line 16 may be disposed in and matching with each pixel unit and a position of each touch control signal line 16 in a corresponding pixel unit may be the same. For example, the touch control signal line 16 may be located at one side of a data line 12 with which a first sub-pixel P1 of a corresponding pixel unit is connected. One column of pixel units may be disposed between two adjacent touch control signal lines 16. Three data lines 12 may be disposed between two adjacent touch control signal lines 16 and the three data lines 12 may be electrically connected with switching transistors 14 of three columns of sub-pixels, respectively. However, the present embodiment is not limited thereto. In other examples, two or three touch control signal lines may be disposed in and matching with at least one pixel unit. For example, two touch control signal lines may be located at a same side of a data line connected with a first sub-pixel of a corresponding pixel unit; or, three touch control signal lines may be disposed correspondingly in at least one pixel unit, and three data lines connected with three sub-pixels of the pixel unit may be adjacent to the three touch control signal lines in one-to-one correspondence, in other words, a plurality of data lines and a plurality of touch control signal lines may be arranged at intervals along the first direction.

In some examples, a common electrode of a sub-pixel may be multiplexed as a touch control sensing block. In a display stage, a common voltage is provided to a common electrode through a touch control signal line 16 to achieve a display function; and in a touch control stage, a touch control signal detected by the common electrode is transmitted by using the touch control signal line 16 to achieve a touch control function. Common electrodes of a plurality of sub-pixels may be connected with each other to form a touch control sensing block. For example, common electrodes isolated from each other within a plurality of pixel units may be connected with each other to form one touch control sensing block.

FIG. 4 is a schematic diagram of a scanning drive circuit according to at least one embodiment of the present disclosure. In some examples, as shown in FIGS. 1 and 4, the array substrate may further include a scanning drive circuit located in the bezel area BB. The scanning drive circuit may include a first drive circuit 24a located in the left bezel region B1 and a second drive circuit 24b located in the right bezel region B2. The first drive circuit 24a may include a plurality of first drive units 241, and the plurality of first drive units 241 may be a plurality of shift register circuits in a cascade relationship; the second drive circuit 24b may include a plurality of second drive units 242, and the plurality of second drive units 242 may be a plurality of shift register circuits in a cascade relationship. The plurality of first drive units 241 may be sequentially arranged in the left bezel region B1 along the second direction Y, and the plurality of second drive units 242 may be sequentially arranged in the right bezel region B2 along the second direction Y.

In some examples, as shown in FIGS. 1 and 4, one first drive unit 241 may be configured to provide a scanning signal to a row of sub-pixels through one scanning line 11, for example, to provide a scanning signal to a (2i−1)-th row of sub-pixels in the display area, and one second drive unit 242 may be configured to provide a scanning signal to a row of sub-pixels through one scanning line 11, for example, to provide a scanning signal to a (2i)-th row of sub-pixels, wherein i is an integer greater than 0. In other words, a scanning signal of an odd-numbered row of sub-pixels in the display area may be supplied by the first drive circuit 24a, and a scanning signal of an even-numbered row of sub-pixels may be supplied by the second drive circuit 24b, thereby achieving a single-side drive mode in which odd and even rows intersect. However, the present embodiment is not limited thereto. In other examples, a scanning signal of an odd-numbered row of sub-pixels may be provided by the second drive circuit, and a scanning signal of an even-numbered row of sub-pixels may be provided by the first drive circuit. In this example, a drive mode in which odd and even rows intersect may reduce a quantity of drive units, which is beneficial to achieve narrowing of a bezel.

In some examples, as shown in FIG. 4, the plurality of first drive units 241 included in the first drive circuit 24a may be connected in cascade, for example, the first drive circuit 24a may include a first-stage first drive unit to an N-th-stage first drive unit, and N is an integer greater than 0. Herein, an output terminal of an a-th-stage first drive unit may provide an input signal to an (a+2)-th-stage first drive unit, and an output terminal of the (a+2)-th-stage first drive unit may provide a reset signal to the a-th-stage first drive unit; a is an integer greater than 0.

In some examples, each stage first drive unit of the first drive circuit 24a may be configured to provide a scanning signal to one odd-numbered sub-pixel row. For example, a first-stage first drive unit may be configured to provide a scanning signal to a first row of sub-pixels, a second-stage first drive unit may be configured to provide a scanning signal to a third row of sub-pixels, a third-stage first drive unit may be configured to provide a scanning signal to a fifth row of sub-pixels, a fourth-stage first drive unit may be configured to provide a scanning signal to a seventh row of sub-pixels, and so on.

In some examples, as shown in FIG. 4, the plurality of second drive units 242 included in the second drive circuit 24b may be connected in cascade, for example, the second drive circuit 24b may include a first-stage second drive unit to an M-th-stage second drive unit, and M is an integer greater than 0. Herein, an output terminal of a b-th-stage second drive unit may provide an input signal to a (b+2)-th-stage second drive unit, and an output terminal of the (b+2)-th-stage second drive unit may provide a reset signal to the b-th-stage second drive unit; b is an integer greater than 0.

In some examples, each stage second drive unit of the second drive circuit 24b may be configured to provide a scanning signal to one even-numbered sub-pixel row. For example, a first-stage second drive unit may be configured to provide a scanning signal to a second row of sub-pixels, a second-stage second drive unit may be configured to provide a scanning signal to a fourth row of sub-pixels, a third-stage second drive unit may be configured to provide a scanning signal to a sixth row of sub-pixels, a fourth-stage second drive unit may be configured to provide a scanning signal to an eighth row of sub-pixels, and so on. In some examples, a sum of N and M may be equal to a total number of rows of sub-pixels of the display area.

In some examples, each drive unit of the plurality of first drive units 241 and the plurality of second drive units 242 may include at least a first control transistor, a second control transistor, and a first capacitor. Herein, a control electrode of the first control transistor may be electrically connected with a reset signal line, a first electrode may be electrically connected with a first voltage line, and a second electrode may be electrically connected with a control electrode of the second control transistor. A second electrode of the second control transistor may be electrically connected with an output terminal of the drive unit. A first electrode of the first capacitor may be electrically connected with the control electrode of the second control transistor, and a second electrode of the first capacitor may be electrically connected with the output terminal of the drive unit. A connection point of the second electrode of the first control transistor, the first electrode of the first capacitor, and the control electrode of the second control transistor may be referred to as a pull-up node PU. For example, taking a case in which the first control transistor and the second control transistor are both N-type transistors as an example, after a potential of the pull-up node PU is pulled down, the second control transistor cannot be turned on, and the output terminal of the drive unit stops outputting. The first voltage line may be configured to provide a first voltage signal at a low level.

In some examples, as shown in FIG. 4, a reset signal line with which an a-th-stage first drive unit of the first drive circuit 24a is connected may be electrically connected with an output terminal of an (a+2)-th-stage first drive unit. A reset signal line with which a b-th-stage second drive unit of the second drive circuit 24b is connected may be electrically connected with an output terminal of a (b+2)-th-stage second drive unit.

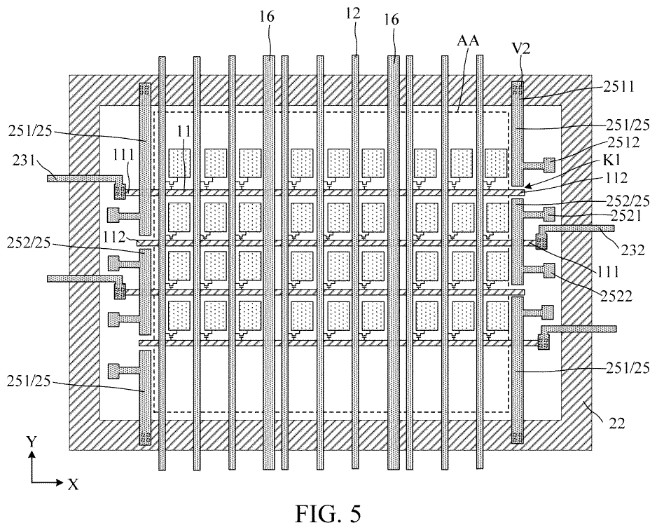

FIG. 5 is a schematic diagram of a partial film layer in FIG. 1. In some examples, as shown in FIGS. 1 and 5, the scanning line 11 may include a scanning connection end 111 and an extension end 112 which extend to the bezel area BB. Since a single-side drive mode in which odd and even rows intersect is adopted for the array substrate of the present example, the scanning connection end 111 of the scanning line 11 may extend to the left bezel region B1 and be electrically connected with the first drive unit 241 of the first drive circuit, or may extend to the right bezel region B2 and be electrically connected with the second drive unit 242 of the second drive circuit; the extension end 112 of the scanning line 11 may extend to the left bezel region B1 or the right bezel region B2 as an independently disposed end portion. For example, a scanning line 11 electrically connected with a (2i−1)-th row of sub-pixels may include a scanning connection end 111 extending to the left bezel region B1 and an extension end 112 extending to the right bezel region B2, and the scanning connection end 111 extending to the left bezel region B1 may be electrically connected with one first drive unit 241 of the first drive circuit; a scanning line 11 electrically connected with a (2i)-th row of sub-pixels may include an extension end 112 extending to the left bezel region B1 and a scanning connection end 111 extending to the right bezel region B2, and the scanning connection end 111 extending to the right bezel region B2 may be electrically connected with one second drive unit 242 of the second drive circuit.

In some examples, as shown in FIGS. 1 and 5, in the left bezel region B1, scanning connection ends 111 and extension ends 112 of a plurality of scanning lines 11 may be disposed at intervals along the second direction Y. In the right bezel region B2, extension ends 112 and scanning connection ends 111 of a plurality of scanning lines 11 may be disposed at intervals along the second direction Y. An arrangement mode of scanning lines of the present example may achieve a single-side drive method in which odd and even rows intersect.

In some examples, as shown in FIGS. 1 and 5, the array substrate may further include a plurality of first connection lines (e.g., including a plurality of first connection lines 231 and 232) located in the bezel area BB. The plurality of first connection lines 231 may be located in the left bezel region B1, and a first connection line 231 may be configured to electrically connect an output terminal of a first drive unit and a scanning connection end 111 of a scanning line 11 extending to the left bezel region B1. The plurality of first connection lines 232 may be located in the right bezel region B2, and a first connection line 232 may be configured to electrically connect an output terminal of a second drive unit and a scanning connection end 111 of a scanning line 11 extending to the right bezel region B2. The plurality of first connection lines 231 and 232 may be disposed in a same layer, and may be located at a side of a plurality of scanning lines 11 away from the base substrate.

In some examples, a first connection line 231 (or a first connection line 232) may be directly electrically connected with a scanning connection end 111 of a scanning line 11. For example, the scanning line 11 may be located in a first conductive layer, the first connection line 231 or 232 may be located in a second conductive layer, a first insulation layer may be disposed between the first conductive layer and the second conductive layer, and the first connection line 231 or 232 located in the second conductive layer may be electrically connected with the scanning connection end 111 of the scanning line 11 located in the first conductive layer through a via opened in the first insulation layer. However, the present embodiment is not limited thereto.

In some examples, as shown in FIGS. 1 and 5, the array substrate may further include a first common voltage signal line 21 and a second common voltage signal line 22 located in the bezel area BB. The first common voltage signal line 21 may be located at a side of the second common voltage signal line 22 away from the base substrate. The first common voltage signal line 21 may be a ring-shaped trace (wire) surrounding the display area AA, and may have, for example, a rectangular ring shape. The second common voltage signal line 22 may be a ring-shaped trace surrounding the display area AA, and may have, for example, a rectangular ring shape. An orthographic projection of the first common voltage signal line 21 on the base substrate and an orthographic projection of the second common voltage signal line 22 on the base substrate may be at least partially overlapped. For example, the orthographic projection of the first common voltage signal line 21 on the base substrate may cover the orthographic projection of the second common voltage signal line 22 on the base substrate.

In some examples, as shown in FIG. 1, the first common voltage signal line 21 may be electrically connected with the second common voltage signal line 22 through a plurality of first vias V1, and the first common voltage signal line 21 and the second common voltage signal line 22 may be configured to transmit a common voltage Vcom. For example, the first common voltage signal line 21 may be located in a second transparent conductive layer, the second common voltage signal line 22 may be located in a first conductive layer, a first insulation layer, a second insulation layer, a third insulation layer, and a fourth insulation layer may be disposed between the first conductive layer and the second transparent conductive layer, the fourth insulation layer may be provided with a plurality of first vias V1 exposing a part of a surface of the second common voltage signal line 22, and the first common voltage signal line 21 may be electrically connected with the second common voltage signal line 22 through the plurality of first vias V1.

In some examples, as shown in FIG. 1, the plurality of first vias V1 are divided into a plurality of groups. For example, a group of first vias VI may include four first vias V1 arranged in a 2×2 array. The plurality of groups of first vias V1 may be arranged in a ring shape around the display area AA, so as to ensure that a plurality of positions of the first common voltage signal line 21 are all electrically connected with the second common voltage signal line 22, and uniform transmission of a common voltage is ensured.

In some examples, as shown in FIGS. 1 and 5, the array substrate may further include at least one dummy wire 25 located in the bezel area BB and extending along the second direction Y. In this example, a dummy wire 25 is disposed in the left bezel region B1, and a dummy wire 25 is disposed in the right bezel region B2. In this example, dummy wires are disposed in both the left bezel region and the right bezel region to ensure process uniformity of the array substrate. A quantity of dummy wires may be determined according to a resolution of the array substrate and a quantity of touch control sensing blocks. The present embodiment is not limited thereto. In other examples, the left bezel region B1 may be provided with two dummy wires 25, and the right bezel region B2 may be provided with two dummy wires 25.

In some examples, as shown in FIGS. 1 and 5, a dummy wire 25 may be disposed in a same layer as a data line 12 and a touch control signal line 16 of the display area AA. In the left bezel region B1 and the right bezel region B2, dummy wires 25 may be located at a side of the first common voltage signal line 21 and the second common voltage signal line 22 close to the display area AA.

In some examples, as shown in FIGS. 1 and 5, the dummy wire 25 located in the right bezel region B2 may include a plurality of dummy wire segments sequentially arranged along the second direction Y and extending along the second direction Y. The plurality of dummy wire segments may include two first dummy wire segments 251 and a plurality of second dummy wire segments 252, and in FIGS. 1 and 5, illustration is made by taking one second dummy wire segment 252 as an example. A plurality of second dummy wire segments 252 may be sequentially arranged between two first dummy wire segments 251. A quantity of second dummy wire segments in the right bezel region B2 in the present example may be determined according to a quantity of extension ends of scanning lines in the right bezel region B2. For example, if a quantity of extension ends of scanning lines in the right bezel region B2 is N, a quantity of second dummy wire segments 252 of a dummy wire may be N−1.

In some examples, as shown in FIGS. 1 and 5, orthographic projections of two first dummy wire segments 251 of a dummy wire 25 located in the right bezel region B2 on the base substrate and an orthographic projection of a scanning line 11 of the array substrate on the base substrate may not be overlapped. An orthographic projection of at least one second dummy wire segment 252 of the dummy wire 25 on the base substrate may be partially overlapped with an orthographic projection of a scanning connection end 111 of one scanning line 11 on the base substrate.

In some examples, as shown in FIGS. 1 and 5, a first dummy wire segment 251 of a dummy wire 25 located in the right bezel region B2 may be provided with a first dummy connection portion 2511 at a side away from a second dummy wire segment 252, and the first dummy connection portion 2511 and the first dummy wire segment 251 may have an interconnected integral structure. The first dummy connection portion 2511 may extend at least along the second direction Y, and may be electrically connected with the second common voltage signal line 22 through a plurality of second vias V2. The first dummy wire segment 251 may be provided with a second dummy connection portion 2512 at a side close to one end of the second dummy wire segment 252 and away from the display area AA, and the second dummy connection portion 252 may extend at least along the first direction X and be electrically connected with the first common voltage signal line 21. The second dummy wire segment 252 may be provided with a third dummy connection portion 2521 and a fourth dummy connection portion 2522 at a side away from the display area AA. The third dummy connection portion 2521 and the fourth dummy connection portion 2522 of the second dummy wire segment 252 may be located at two sides of a scanning connection end 111 of one scanning line 11 along the second direction Y. The third dummy connection portion 2521, the fourth dummy connection portion 2522, and the second dummy wire segment 252 may have an interconnected integral structure. For example, the third dummy connection portion 2521 is connected with one end portion of the second dummy wire segment 252, and the fourth dummy connection portion 2522 is connected with the other end portion of the second dummy wire segment 252. The third dummy connection portion 2521 and the fourth dummy connection portion 2522 may be located at a side of the second common voltage signal line 22 close to the display area AA, and may be electrically connected with the first common voltage signal line 21. In the present example, the first dummy wire segment 251 of the dummy wire is electrically connected with the second common voltage signal line 22 and the first common voltage signal line 21, and the second dummy wire segment 252 is electrically connected with the first common voltage signal line 21 to achieve receiving a common voltage, which may prevent capacitance of a surrounding touch control sensing block from being affected by capacitive coupling generated by floating connection of the dummy wire, and avoid affecting a touch control effect.

In some examples, as shown in FIGS. 1 and 5, a first fracture may be disposed between adjacent dummy wire segments arranged sequentially along the second direction Y of a dummy wire 25 located in the right bezel region B2, for example, a first fracture K1 may be disposed between a first dummy wire segment 251 and a second dummy wire segment 252. The first fracture K1 corresponds to a position where an extension end 112 of one scanning line 11 is located. A length of the first fracture K1 along the second direction Y may be greater than a length of the extension end 112 of the scanning line 11 along the second direction Y. By disposing the first fracture, orthographic projections of the dummy wire 25 and the extension end 112 of the scanning line 11 on the base substrate are not overlapped, which may prevent intersection of the dummy wire 25 and the extension end 112 of the scanning line 11, and may reduce a risk of a short circuit between the dummy wire 25 and the scanning line 11 caused by breakdown of an insulation layer caused by electrostatic discharge at the extension end 112 of the scanning line 11, thereby improving poor horizontal stripes-type functional display caused by this.

A design of a dummy wire in the left bezel region is similar to a design of a dummy wire in the right bezel region, so it will not be repeated here.

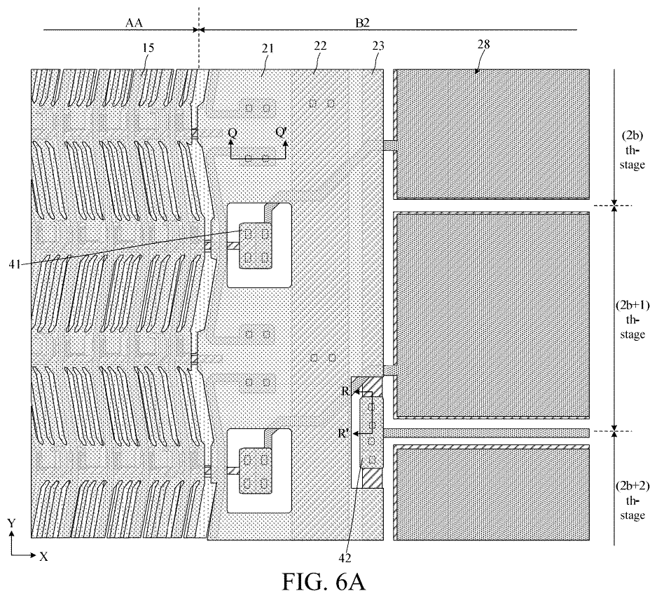

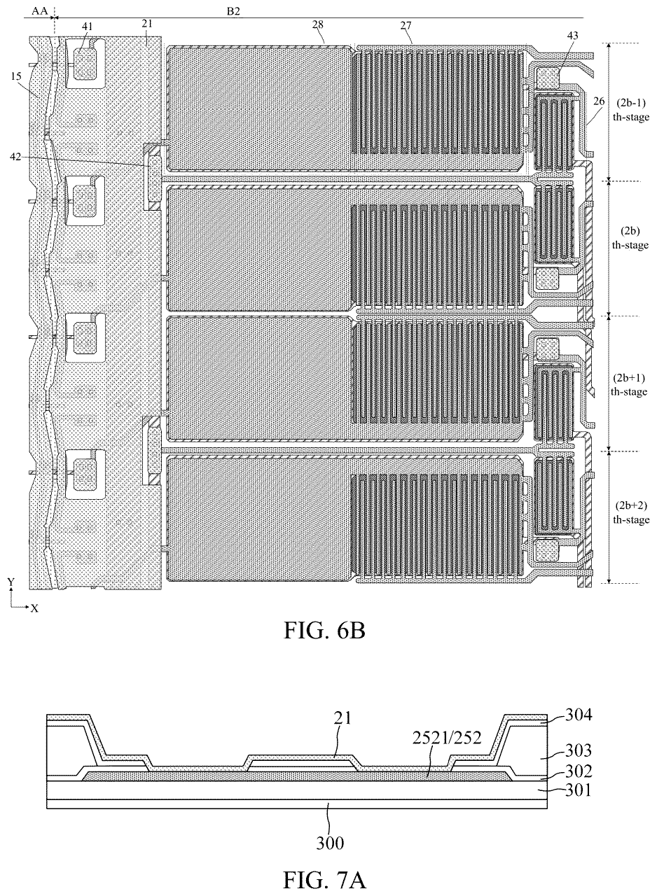

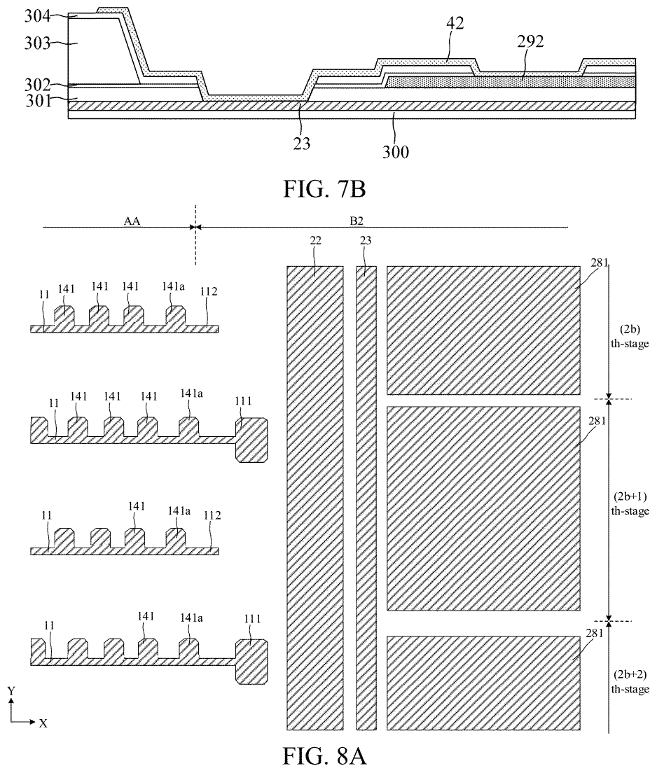

FIG. 6A is a partial plan schematic view of a boundary region between a display area and a right bezel region according to at least one embodiment of the present disclosure. FIG. 6B is a partial plan schematic view of a right bezel region according to at least one embodiment of the present disclosure. In FIG. 6A, partial structures of a (2b)-th-stage second drive unit, a (2b+1)-th-stage second drive unit, and a (2b+2)-th-stage second drive unit in the right bezel region B2 are schematically illustrated. In FIG. 6B, partial structures of a (2b−1)-th-stage second drive unit, a (2b)-th-stage second drive unit, a (2b+1)-th-stage second drive unit, and a (2b+2)-th-stage second drive unit in the right bezel region B2 are schematically illustrated. Herein, b is an integer greater than 0. FIG. 7A is a schematic partial sectional view along a Q-Q′ direction in FIG. 6A. FIG. 7B is a schematic partial sectional view along an R-R′ direction in FIG. 6A. In the present example, one column of dummy sub-pixels may be disposed at a side of a plurality of columns of sub-pixels close to the right bezel region B2.

In some examples, as shown in FIG. 7A and FIG. 7B, an array substrate may include: a base substrate 300, and a first conductive layer, a semiconductor layer, a second conductive layer, a first transparent conductive layer, and a second transparent conductive layer that are sequentially disposed on the base substrate 300. A first insulation layer 301 may be disposed between the first conductive layer and the semiconductor layer, a second insulation layer 302 and a third insulation layer 303 may be disposed between the second conductive layer and the first transparent conductive layer, and a fourth insulation layer 304 may be disposed between the first transparent conductive layer and the second transparent conductive layer. The semiconductor layer and the second conductive layer may be in direct contact. Herein, the first insulation layer 301, the second insulation layer 302, and the fourth insulation layer 304 may be inorganic insulation layers, and the third insulation layer 303 may be an organic insulation layer. The present embodiment is not limited thereto.

A technical solution of the present embodiment will be further illustrated below through a preparation process of the array substrate of the present exemplary embodiment. A “patterning process” mentioned in the present disclosure includes photoresist coating, mask exposure, development, etching, photoresist stripping, and the like for a metal material, an inorganic material, or a transparent conductive material, and includes organic material coating, mask exposure, development, and the like for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire preparation process, the “thin film” may also be called a “layer”. If the “thin film” need to be processed through the patterning process in the entire preparation process, the “thin film” is called a “thin film” before the patterning process is performed and is called a “layer” after the patterning process is performed. At least one “pattern” is contained in the “layer” which has been processed through the patterning process.

“A and B are disposed in a same layer” or “A and B being disposed in a same layer” mentioned in the present disclosure means that A and B are formed simultaneously through a same patterning process, and a “thickness” of a film layer is a dimension of the film layer in a direction perpendicular to a display substrate. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A overlaps with the boundary of the orthographic projection of B. In the present example, “a shape of A” refers to a shape of an orthographic projection of A on a base substrate.

The preparation process of the array substrate according to the present embodiment includes following acts.
(1) A base substrate is provided. In some examples, the base substrate may be a transparent base substrate, for example, a quartz base substrate, a glass base substrate, or an organic resin base substrate. However, the present embodiment is not limited thereto.
(2) A first conductive layer is formed. In some examples, a first conductive thin film is deposited on the base substrate, and the first conductive thin film is patterned through a patterning process to form the first conductive layer. In some examples, the first conductive layer may also be referred to as a first gate metal layer.

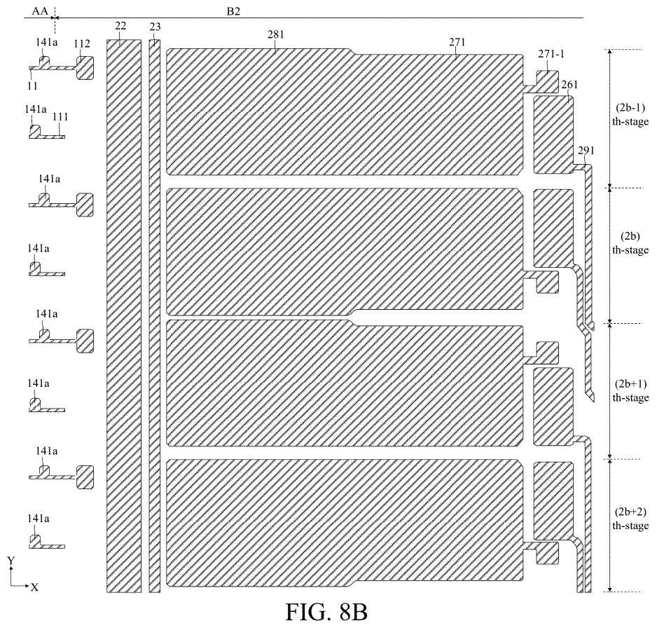

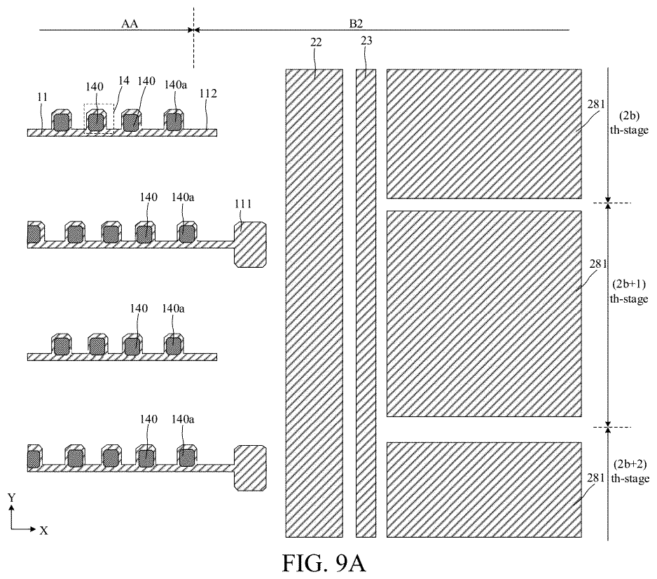

FIG. 8A is a schematic plan view of an array substrate after a first conductive layer is formed in FIG. 6A. FIG. 8B is a schematic plan view of an array substrate after a first conductive layer is formed in FIG. 6B.

In some examples, as shown in FIGS. 8A and 8B, the first conductive layer may include at least a plurality of scanning lines 11 and control electrodes 141 of a plurality of switching transistors located in a display area AA, a plurality of first dummy control blocks 141a, and a second common voltage signal line 22 located in a right bezel region B2, a first voltage line 23, control electrodes of transistors of a plurality of second drive units (for example, including a control electrode 261 of a first control transistor and a control electrode 271 of a second control transistor) and a first electrode plate 281 of a first capacitor, and a reset signal line 291.

In some examples, as shown in FIG. 8A, the plurality of scanning lines 11 in the display area AA may extend along a first direction X and be sequentially arranged along a second direction Y. A shape of a scanning line 11 may be substantially a straight line extending along the first direction X. Control electrodes 141 of a plurality of switching transistors arranged along the first direction X may be located at a same side of one scanning line 11 along the second direction Y, and may have an interconnected integral structure with the scanning line 11. A shape of a control electrode 141 of a switching transistor may be substantially a rectangle, and the rectangle may have chamfers or rounded corners.

In some examples, as shown in FIG. 8A, a first dummy control block 141a may be located at a side of the control electrodes 141 of the plurality of switching transistors arranged along the first direction X close to the right bezel region B2. The plurality of first dummy control blocks 141a may be arranged in a boundary region between the display area AA and the right bezel region B2 along the second direction Y. A first dummy control block 141a and an adjacent scanning line 11 may have an interconnected integral structure. The first dummy control block 141a may serve as a control electrode of a switching transistor of a dummy sub-pixel.

In some examples, as shown in FIGS. 8A and 8B, in the right bezel region B2, extension ends 112 and scanning connection ends 111 of a plurality of scanning lines 11 may be disposed at intervals along the second direction Y and located at a side of the second common voltage signal line 22 close to the display area AA. A distance along the first direction X between a scanning connection end 111 and the second common voltage signal line 22 may be smaller than a distance along the first direction X between an extension end 112 and the second common voltage signal line 22.

In some examples, as shown in FIGS. 8A and 8B, the second common voltage signal line 22 may extend at least along the second direction Y within the right bezel region B2; the first voltage line 23 may extend at least along the second direction Y within the right bezel region B2. The first voltage line 23 may be located at a side of the second common voltage signal line 22 away from the display area AA. The first voltage line 23 may be configured to supply a low-level first voltage signal VGL to the plurality of second drive units.

In some examples, as shown in FIGS. 8A and 8B, a second drive unit may be located at a side of the first voltage line 23 away from the display area AA. A first electrode plate 281 of a first capacitor of the second drive unit may serve as a first electrode of the first capacitor, and first electrode plates 281 of first capacitors of a plurality of cascaded second drive units may be sequentially arranged along the second direction Y. An orthographic projection of the first electrode plate 281 of the first capacitor on the base substrate may be substantially of a rectangle.

In some examples, as shown in FIG. 8B, the first electrode plate 281 of the first capacitor of the second drive unit and the control electrode 271 of the second control transistor may have an interconnected integral structure. The control electrode 271 of the second control transistor may be located at a side of the first electrode plate 281 of the first capacitor away from the display area AA. A shape of the control electrode 271 of the second control transistor may be substantially a rectangle. The control electrode 271 of the second control transistor may be provided with a control connection block 271-1 at a side away from the display area AA, one end of the control connection block 271-1 is connected with the control electrode 271 of the second control transistor, and the other end of the control connection block 271-1 extends toward a side away from the display area AA along the first direction X. a shape of a control connection block 271-1 of a (2b−1)-th-stage second drive unit may be substantially 9-shaped, and a shape of a control connection block 271-1 of a (2b)-th-stage second drive unit may be substantially P-shaped. The control connection block 271-1 and the control electrode 271 of the second control transistor may be of an interconnected integral structure.

In some examples, as shown in FIG. 8B, the control electrode 261 of the first control transistor may be located at a side of the control electrode 271 of the second control transistor away from the display area AA along the first direction X. A control electrode 261 of a first control transistor of the (2b−1)-th-stage second drive unit may be located at a side of the control connection block 271-1 of the second control transistor along an opposite direction of the second direction Y, and a control electrode 261 of a first control transistor of the (2b)-th-stage second drive unit may be located at a side of the control connection block 271-1 of the second control transistor along the second direction Y. A shape of the control electrode 261 of the first control transistor may be substantially a rectangle. An area of the control electrode 261 of the first control transistor may be smaller than an area of the control electrode 271 of the second control transistor.

In some examples, as shown in FIG. 8B, a first conductive layer pattern of the (2b−1)-th-stage second drive unit and a first conductive layer pattern of the (2b)-th-stage second drive unit may be substantially symmetrical about a midline of the two in the second direction Y. The first conductive layer pattern of the (2b)-th-stage second drive unit and a first conductive layer pattern of a (2b+1)-th-stage second drive unit may be substantially symmetrical about a midline of the two in the second direction Y.

In some examples, as shown in FIG. 8B, the reset signal line 291 may be located at a side of the control electrode 261 of the first control transistor away from the display area AA, and the reset signal line 291 and the control electrode 261 of the first control transistor may be of an interconnected integral structure. For example, a reset signal line 291 with which the control electrode 261 of the first control transistor of the (2b−1)-th-stage second drive unit is connected may be electrically connected with an output terminal of the (2b+1)-th-stage second drive unit.
(3) A semiconductor layer is formed. In some examples, a first insulation thin film and a semiconductor thin film are sequentially deposited on the base substrate, and the semiconductor thin film is patterned through a patterning process to form a first insulation layer and a semiconductor layer disposed on the first insulation layer.

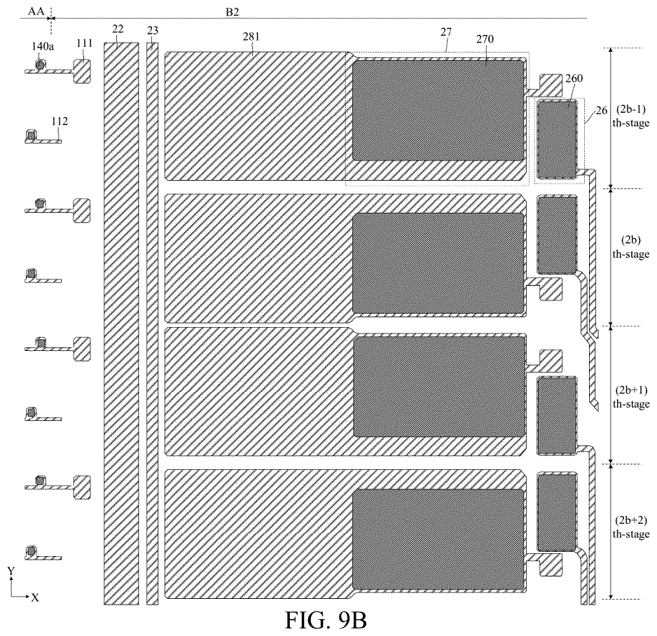

FIG. 9A is a schematic plan view of the array substrate after a semiconductor layer is formed in FIG. 6A. FIG. 9B is a schematic plan view of the array substrate after a semiconductor layer is formed in FIG. 6B.

In some examples, as shown in FIGS. 9A and 9B, the semiconductor layer may include at least active layers 140 of a plurality of switching transistors 14 located in the display area AA and active layers of a plurality of transistors of a second drive unit located in the right bezel region B2 (for example, at least including an active layer 260 of a first control transistor 26 and an active layer 270 of a second control transistor 27).

In some examples, as shown in FIG. 9A, an active layer 140 of a switching transistor 14 may be substantially rectangular in shape and have chamfers or rounded corners. An orthographic projection of a control electrode 141 of the switching transistor 14 on the base substrate may cover an orthographic projection of the active layer 140 on the base substrate.

In some examples, as shown in FIG. 9A, at a junction of the display area AA and the right bezel region B2, the semiconductor layer may further include a plurality of first dummy active blocks 140a. The plurality of first dummy active blocks 140a may be arranged in one column along the second direction Y, and may be located at a side of the active layers 140 of the plurality of switching transistors 14 close to the right bezel region B2. A first dummy active block 140 a may serve as an active layer of a switching transistor of a dummy sub-pixel. In this example, by disposing a plurality of first dummy active blocks 140a, it is possible to ensure uniformity of film layer preparation.

In some examples, as shown in FIG. 9A, the first dummy active block 140a may be substantially rectangular in shape and have chamfers or rounded corners. An orthographic projection of the first dummy active block 140a on the base substrate may be located within a range of an orthographic projection of the first dummy control block 141a on the base substrate. In some examples, as shown in FIG. 9B, the active layer 260 of the first control transistor 26 may be substantially rectangular in shape and have chamfers or rounded corners. An orthographic projection of the control electrode 261 of the first control transistor 26 on the base substrate may cover an orthographic projection of the active layer 260 on the base substrate.

In some examples, as shown in FIG. 9B, the active layer 270 of the second control transistor 27 may be substantially rectangular in shape and have chamfers or rounded corners. An orthographic projection of the control electrode 271 of the second control transistor 27 on the base substrate may cover an orthographic projection of the active layer 270 on the base substrate.

In some examples, as shown in FIG. 9B, a semiconductor layer pattern of the (2b−1)-th-stage second drive unit and a semiconductor layer pattern of the (2b)-th-stage second drive unit may be substantially symmetrical about a midline of the two in the second direction Y. The semiconductor layer pattern of the (2b)-th-stage second drive unit and a semiconductor layer pattern of a (2b+1)-th-stage second drive unit may be substantially symmetrical about a midline of the two in the second direction Y.

In some examples, an active layer of each transistor may include: a first region, a second region, and a channel region located between the first region and the second region. Herein, a material of the semiconductor layer may include, for example, one or more materials such as amorphous Silicon (a-Si), polycrystalline Silicon (p-Si), hexathiophene, polythiophene, etc. The channel region may not be doped with impurities, and has characteristics of a semiconductor. The first region and the second region may be doped regions on both sides of the channel region, and are doped with impurities, and thus have conductivity. The impurities may be different according to a type of a transistor. In some examples, a doped region of the active layer may be interpreted as a source or a drain of a transistor. A part of active layers between transistors may be interpreted as wiring doped with impurities, and may be used for electrically connecting the transistors.
(4) A second conductive layer is formed. In some examples, a second conductive thin film is deposited on the base substrate on which the aforementioned structures are formed, and the second conductive thin film is patterned through a patterning process to form a second conductive layer. In some examples, the second conductive layer may also be referred to as a source-drain metal layer.

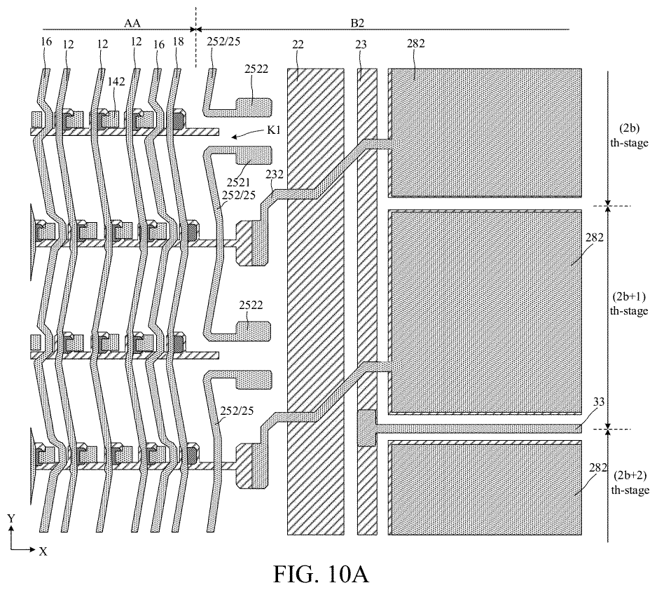

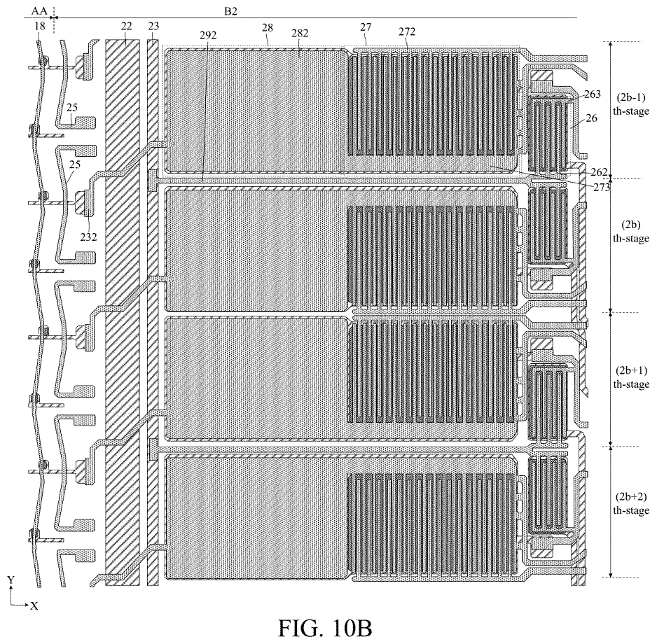

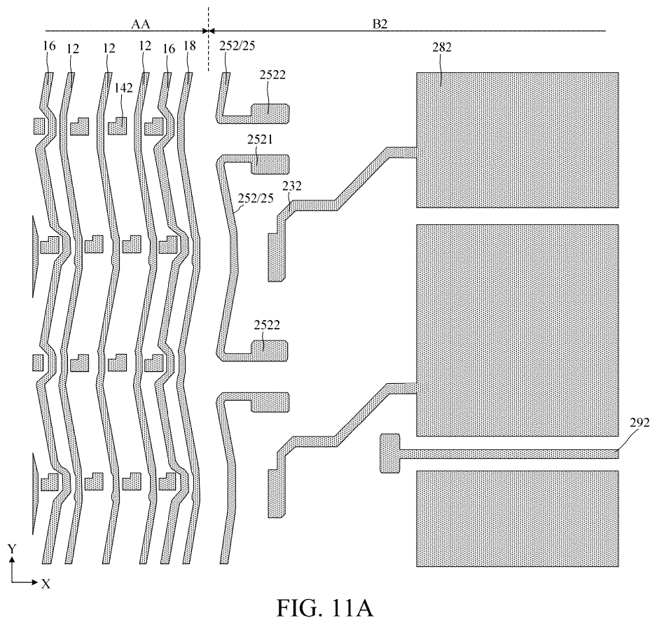

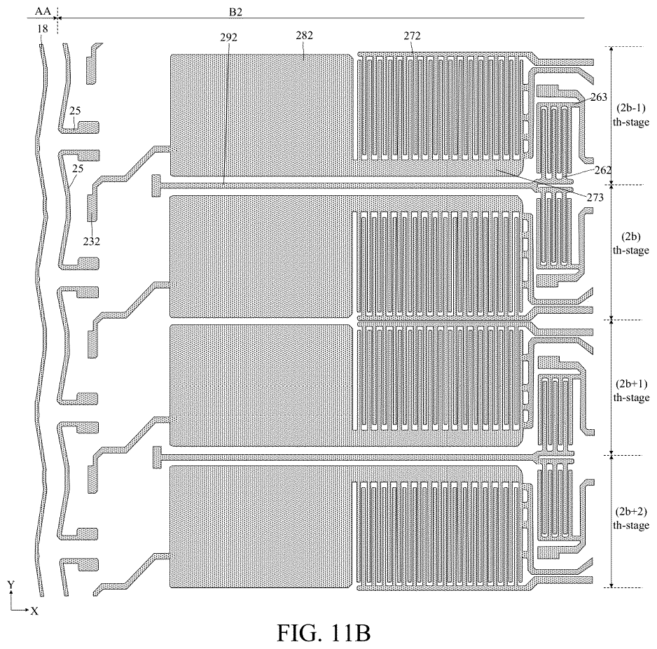

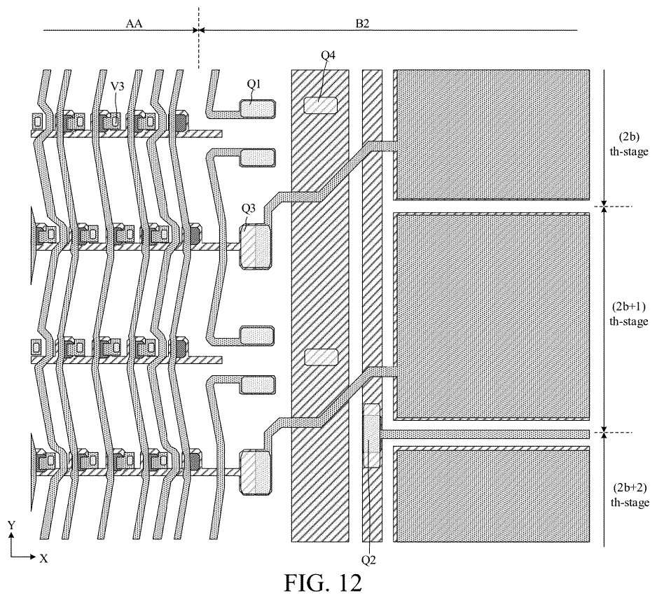

FIG. 10A is a schematic plan view of the array substrate after a second conductive layer is formed in FIG. 6A. FIG. 10B is a schematic plan view of the array substrate after a second conductive layer is formed in FIG. 6B. FIG. 11A is a schematic diagram of the second conductive layer in FIG. 10A. FIG. 11B is a schematic diagram of the second conductive layer in FIG. 10B.

In some examples, as shown in FIGS. 10A to 11B, the second conductive layer may include at least a plurality of data lines 12 located in the display area AA, a plurality of touch control signal lines 16, second electrodes 142 of a plurality of switching transistors, and a dummy data line 18; a dummy wire 25 located in the right bezel region B2, a first connection line 232, first electrodes and second electrodes of a plurality of transistors of a plurality of second drive units (for example, including a first electrode 272 and a second electrode 273 of a second control transistor, a first electrode 262 and a second electrode 263 of a first control transistor), a second electrode plate 282 of a first capacitor, and a second connection line 292.

In some examples, as shown in FIGS. 10A and 11A, a shape of a data line 12 in the display area AA may be substantially a shape of a polyline extending along the second direction Y. An orthographic projection of the data line 12 on the base substrate is at least partially overlapped with an orthographic projection of a first region of an active layer 140 of a switching transistor on the base substrate. An overlapping portion of the data line 12 and the active layer 140 of the switching transistor may serve as a first electrode of the switching transistor.

In some examples, as shown in FIGS. 10A and 11A, a second electrode 142 of a switching transistor may be substantially L-shaped. An orthographic projection of the second electrode 142 of the switching transistor on the base substrate is at least partially overlapped with an orthographic projection of a second region of an active layer 140 of the switching transistor on the base substrate.

In some examples, as shown in FIGS. 10A and 11A, a shape of a touch control signal line 16 of the display area AA may be substantially a shape of a polyline extending along the second direction Y. Three data lines 12 may be arranged between two adjacent touch control signal lines 16.

In some examples, as shown in FIGS. 10A and 11A, the dummy data line 18 may be located at a side of the touch control signal line 16 close to the right bezel region B2. The dummy data line 18 may be connected with a column of dummy sub-pixels. A shape of the dummy data line 18 may be substantially a shape of a polyline extending along the second direction Y. An orthographic projection of the dummy data line 18 on the base substrate is partially overlapped with orthographic projections of the plurality of first dummy active blocks 140a on the base substrate.

In some examples, as shown in FIGS. 10A to 11B, the right bezel region B2 is provided with a dummy wire 25. The dummy wire 25 is located at a side of the dummy data line 18. The dummy wire 25 may include at least a plurality of second dummy wire segments 252. A second dummy wire segment 252 may be substantially sigma-shaped. An orthographic projection of the second dummy wire segment 252 on the base substrate is overlapped with an orthographic projection of a scanning line of which a scanning connection end 111 extends to the right bezel region B2, on the base substrate. A third dummy connection portion 2521 and a fourth dummy connection portion 2522 of the second dummy wire segment 252 may be located at two sides of a scanning connection end 111 of one scanning line 11 along the second direction Y. The third dummy connection portion 2521 and the fourth dummy connection portion 2522 of the second dummy wire segment 252, and the scanning connection end 111 of the scanning line may be aligned in the second direction Y. A first fracture K1 may be disposed between adjacent second dummy wire segments 252, and an extension end 112 of a scanning line may be inserted into the first fracture K1.

In some examples, as shown in FIGS. 10A to 11B, a shape of the first connecting line 232 may be substantially a shape of a polyline extending along the first direction X. An orthographic projection of the first connection line 232 on the base substrate is overlapped with orthographic projections of the second common voltage signal line 22 and the first voltage line 23 on the base substrate. An orthographic projection of a first end portion of the first connection line 232 on the base substrate is partially overlapped with an orthographic projection of a scanning connection end 111 of a scanning line on the base substrate. A second end portion of the first connection line 232 may be electrically connected with an output terminal of a second drive unit, for example, the first end portion of the first connection line 232 and the output terminal of the second drive unit may be of an interconnected integral structure.

In some examples, as shown in FIGS. 10B and 11B, an orthographic projection of a first electrode 272 of a second control transistor of a second drive unit on the base substrate is partially overlapped with an orthographic projection of an active layer 270 on the base substrate, and the first electrode 272 may be substantially in a comb-toothed shape. An orthographic projection of a second electrode 273 of the second control transistor on the base substrate is partially overlapped with the orthographic projection of the active layer 270 on the base substrate, and the second electrode 273 may be substantially in a comb-toothed shape. Comb-tooth structures of the first electrode 272 and the second electrode 273 of the second control transistor may be intersected and disposed. The second electrode 273 of the second control transistor and the second electrode plate 282 of the first capacitor may be of an interconnected integral structure. The second electrode plate 282 of the first capacitor may serve as a second electrode of the first capacitor and may also serve as an output terminal of the second drive unit, and is electrically connected with the first connection line 232. An orthographic projection of the first electrode 262 of the first control transistor of the second drive unit on the base substrate is partially overlapped with an orthographic projection of an active layer 260 on the base substrate, and the first electrode 262 may be substantially comb-toothed. An orthographic projection of the second electrode 263 of the first control transistor on the base substrate is partially overlapped with the orthographic projection of the active layer 260 on the base substrate, and the second electrode 263 may be substantially in a comb-toothed shape. Comb-tooth structures of the first electrode 262 and the second electrode 263 of the first control transistor may be intersected and disposed.

In some examples, as shown in FIGS. 10B and 11B, a first electrode 262 of a first control transistor of a (2b−1)-th-stage second drive unit and a first electrode 262 of a first control transistor of a (2b)-th-stage second drive unit may be electrically connected with a same second connection line 292. For example, the first electrode 262 of the first control transistor of the (2b−1)-th-stage second drive unit, the first electrode 262 of the first control transistor of the (2b)-th-stage second drive unit, and one second connection line 292 may be of an interconnected integral structure. The second connection line 292 may be located between a second electrode plate 282 of a first capacitor of the (2b−1)-th-stage second drive unit and a second electrode plate 282 of a first capacitor of the (2b)-th-stage second drive unit. An orthographic projection of an end portion of the second connection line 292 on the base substrate and an orthographic projection of the first voltage line 23 on the base substrate may be overlapped. In the present example, two adjacent second drive units may be electrically connected with the first voltage line 23 through a same second connection line.

In some examples, as shown in FIGS. 10B and 11B, a second conductive layer pattern of a (2b−1)-th-stage second drive unit and a second conductive layer pattern of a (2b)-th-stage second drive unit may be substantially symmetrical about the second connection line 292. The second conductive layer pattern of the (2b)-th-stage second drive unit and a second conductive layer pattern of a (2b+1)-th-stage second drive unit may be substantially symmetrical about a midline of the two along the second direction Y. An arrangement mode of second drive units in this example is beneficial to circuit arrangement and saves space.
(5) A second insulation layer and a third insulation layer are formed. In some examples, a second insulation thin film is deposited on the base substrate, on which the aforementioned structures are formed, and subsequently, a third insulation thin film is coated, and the third insulation thin film is patterned through a patterning process to form the third insulation layer, and the second insulation thin film is patterned through a patterning process to form the second insulation layer. In some examples, the second insulation layer may also be referred to as a first passivation layer (PVX1).

FIG. 12 is a schematic plan view of the array substrate after a third insulation layer is formed in FIG. 6A. In some examples, as shown in FIG. 12, the third insulation layer of the display area AA may be provided with a plurality of vias V3. The third insulation layer and the second insulation layer within a third via V3 may be removed, exposing a portion of a surface of a second electrode 142 of a switching transistor located in the second conductive layer.

In some examples, as shown in FIG. 12, the third insulation layer of the right bezel region B2 may be provided with a plurality of openings, and may include, for example, a first opening Q1, a second opening Q2, a third opening Q3, and a fourth opening Q4. The third insulation layer within the first opening Q1 to the fourth opening Q4 may be removed to expose a surface of the second insulation thin film. An orthographic projection of the first opening Q1 on the base substrate is at least partially overlapped with an orthographic projection of a third dummy connection portion 2511 or a fourth dummy connection portion 2512 of a second dummy wire segment of a dummy wire on the base substrate. An orthographic projection of the second opening Q2 on the base substrate is at least partially overlapped with orthographic projections of the first voltage line 23 and the second connection line 292 on the base substrate. An orthographic projection of the third opening Q3 on the base substrate is partially overlapped with orthographic projections of a scanning connection end 111 of a scanning line and the first connection line 232 on the base substrate. An orthographic projection of the fourth opening Q4 on the base substrate may be located within a range of an orthographic projection of the second common voltage signal line 22 on the base substrate.
(6) A first transparent conductive layer is formed. In some examples, a first transparent conductive thin film is deposited on the base substrate, on which the aforementioned structures are formed, and the first transparent conductive thin film is patterned through a patterning process to form a first transparent conductive layer.

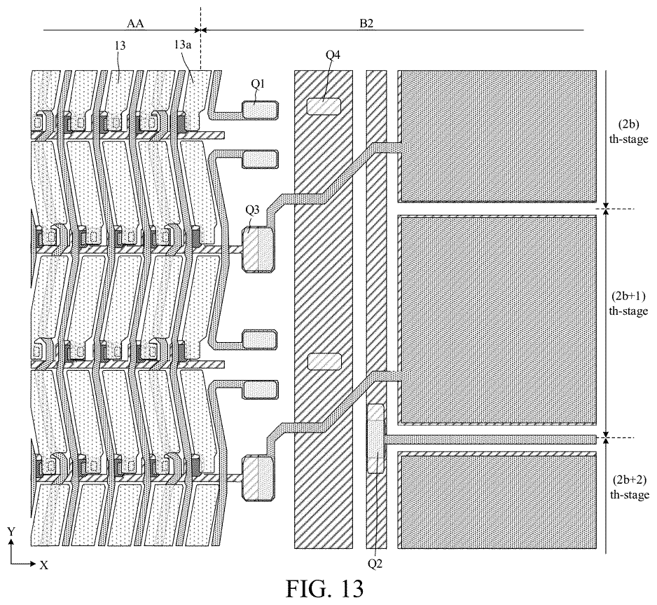

FIG. 13 is a schematic plan view of the array substrate after a first transparent conductive layer is formed in FIG. 6A. In some examples, as shown in FIG. 13, the first transparent conductive layer of the display area AA may include at least a plurality of pixel electrodes 13 and a plurality of dummy pixel electrodes 13a. A pixel electrode 13 may be electrically connected with a second electrode 142 of a switching transistor through a third via V3. An orthographic projection of the pixel electrode 13 on the base substrate may be located within a sub-pixel region defined by intersection of an adjacent data line 12 and an adjacent scanning line 11. An orthographic projection of the touch control signal line 16 on the base substrate may be partially overlapped with the orthographic projection of the pixel electrode 13 on the base substrate. The plurality of dummy pixel electrodes 13a may be arranged in one column along the second direction Y, and may be located at a side of the plurality of pixel electrodes 13 close to the right bezel region B2. An orthographic projection of a dummy pixel electrode 13a on the base substrate may be partially overlapped with an orthographic projection of a first dummy active block 140a on the base substrate. The dummy pixel electrode 13a may serve as a pixel electrode of a dummy sub-pixel.
(7) A fourth insulation layer is formed. In some examples, a fourth insulation thin film is deposited on the base substrate on which the above-mentioned structures are formed, and the fourth insulation thin film is patterned through a patterning process to form a fourth insulation layer. In some examples, the fourth insulation layer may also be referred to as a second passivation layer (PVX2).

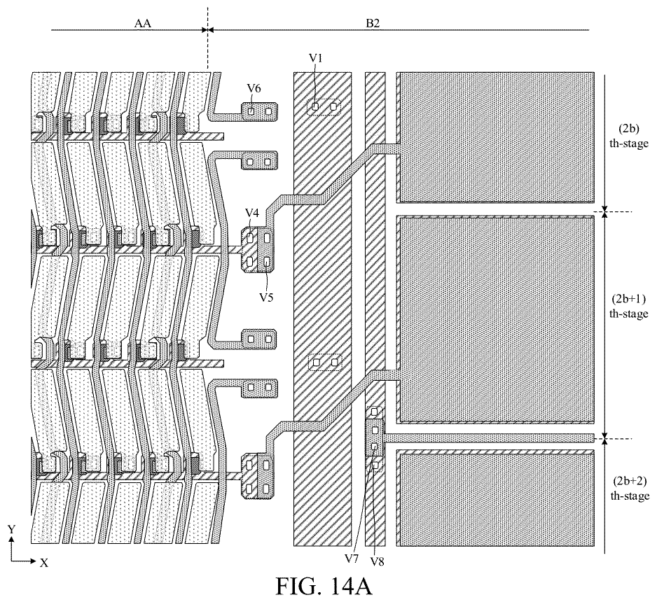

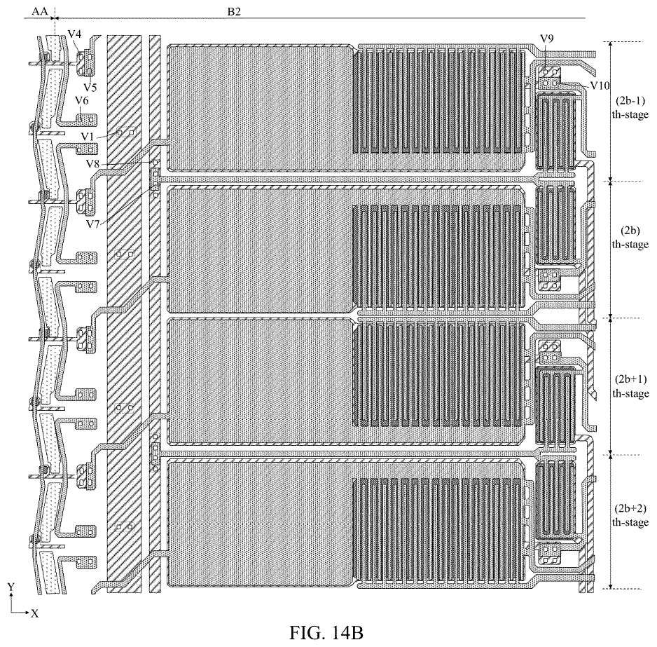

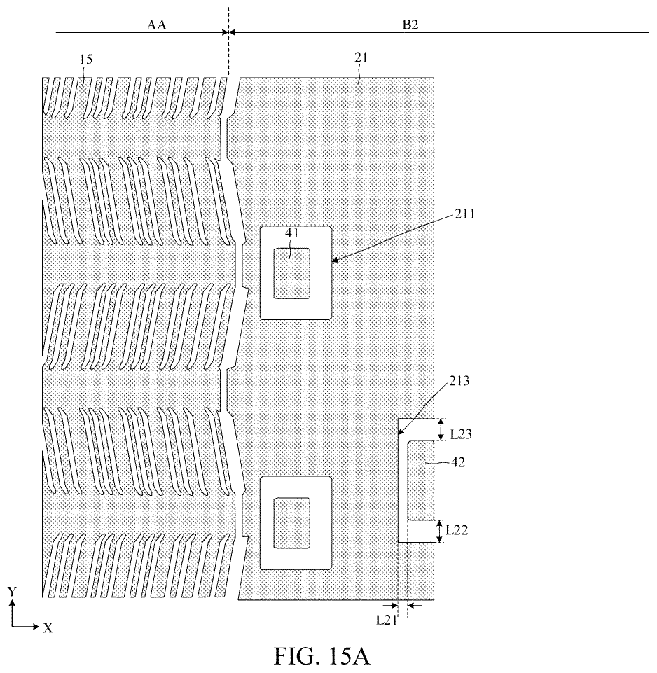

FIG. 14A is a schematic plan view of the array substrate after a fourth insulation layer is formed in FIG. 6A. FIG. 14B is a schematic plan view of the array substrate after a fourth insulation layer is formed in FIG. 6B.

In some examples, as shown in FIGS. 14A and 14B, the fourth insulation layer may be provided with a plurality of vias. For example, a first via V1, a fourth via V4, a fifth via V5, a sixth via V6, a seventh via V7, an eighth via V8, a ninth via V9, and a tenth via V10 may be included.

In some examples, as shown in FIGS. 14A and 14B, an orthographic projection of the first via V1 on the base substrate may be located within a range of an orthographic projection of the fourth opening Q4 on the base substrate; the fourth insulation layer, the third insulation layer, the second insulation layer, and the first insulation layer within the first via V1 may be removed to expose a part of a surface of the second common voltage signal line 22 located in the first conductive layer. Orthographic projections of the fourth via V4 and the fifth via V5 on the base substrate may be located within a range of an orthographic projection of the third opening Q3 on the base substrate. The fourth insulation layer, the third insulation layer, the second insulation layer, and the first insulation layer within the fourth via V4 may be removed to expose a part of a surface of a scanning connection end 111 of a scanning line 11 located in the first conductive layer. The fourth insulation layer, the third insulation layer, and the second insulation layer within the fifth via V5 may be removed, exposing a part of a surface of a first end portion of a first connection line 232 located in the second conductive layer. An orthographic projection of the sixth via V6 on the base substrate may be located within a range of an orthographic projection of the first opening Q1 on the base substrate. The fourth insulation layer, the third insulation layer, and the second insulation layer within the sixth via V6 may be removed to expose a part of a surface of a third dummy connection portion 2521 or a fourth dummy connection portion 2522 of a second dummy wire segment 252 of a dummy wire 25 located in the second conductive layer. Orthographic projections of the seventh via V7 and the eighth via V8 on the base substrate may be located within a range of an orthographic projection of the second opening Q2 on the base substrate. The fourth insulation layer, the third insulation layer, and the second insulation layer within the seventh via V7 may be removed to expose a part of a surface of a second connection line 292 located in the second conductive layer. The fourth insulation layer, the third insulation layer, the second insulation layer, and the first insulation layer within the eighth via V8 may be removed to expose a part of a surface of a first voltage line 23 located in the first conductive layer. Orthographic projections of the ninth via V9 and the tenth via V10 on the base substrate may be located within a range of an orthographic projection of one opening of the third insulation layer on the base substrate. The fourth insulation layer, the third insulation layer, the second insulation layer, and the first insulation layer within the ninth via V9 may be removed to expose a part of a surface of a control connection block 271-1 located in the first conductive layer. The fourth insulation layer, the third insulation layer, and the second insulation layer within the tenth via V10 may be removed, exposing a part of a surface of a second electrode 263 of a first control transistor.

In this example, by first digging away the third insulation layer at a position where a via is formed, it is possible to avoid an influence on an electrical connection effect of a conductive film layer caused by an excessive depth of the via.
(8) A second transparent conductive layer is formed. In some examples, a second transparent conductive thin film is deposited on the base substrate, on which the aforementioned structures are formed, and the second transparent conductive thin film is patterned through a patterning process to form the second transparent conductive layer.

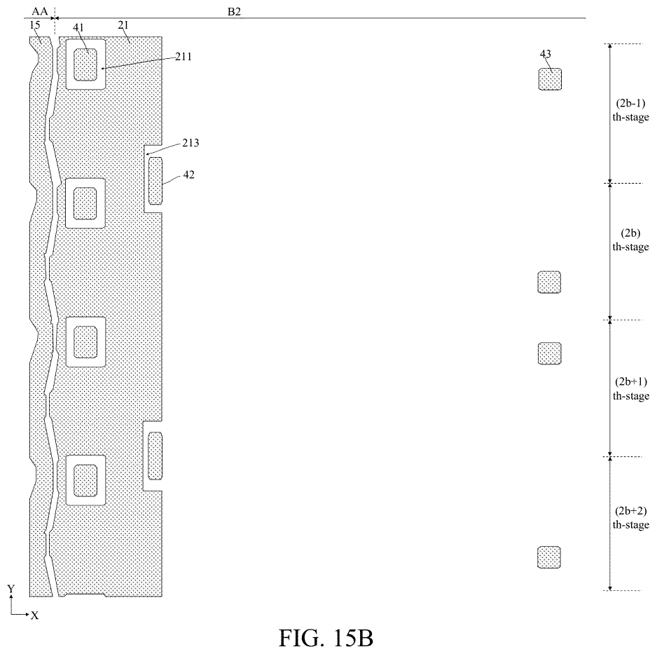

FIG. 15A is a schematic diagram of a second transparent conductive layer in FIG. 6A. FIG. 15B is a schematic diagram of a second transparent conductive layer in FIG. 6B.

In some examples, as shown in FIGS. 6A, 6B, 15A, and 15B, the second transparent conductive layer may include at least a common electrode 15 located in the display area AA, a first common voltage signal line 21 located in the right bezel region B2, and a plurality of connection electrodes (for example, including a first connection electrode 41, a second connection electrode 42, and a third connection electrode 43).

In some examples, as shown in FIG. 15A, common electrodes 15 of a plurality of sub-pixels of the display area AA may be of an interconnected integral structure. A common electrode 15 located within a sub-pixel region may have a plurality of (e.g., three or four) slits. Extension directions of the plurality of slits may intersect with the first direction X and the second direction Y. The common electrode 15 may have slits in two different directions, thereby forming a dual-domain structure. However, the present embodiment is not limited thereto. For example, a common electrode may form a single domain or multi-domain structure.

In some examples, common electrodes 15 of a plurality of sub-pixels are electrically connected with each other to be multiplexed as touch control sensing blocks. For example, a common electrode may be electrically connected with a touch control signal line located in the second conductive layer through vias opened in the fourth insulation layer, the third insulation layer, and the second insulation layer; or, the common electrode may be electrically connected with an electrode connection block located in the first transparent conductive layer through a via opened in the fourth insulation layer, and the electrode connection block is electrically connected with a touch control signal line located in the second conductive layer through vias opened in the third insulation layer and the second insulation layer, thereby achieving an electrical connection between the common electrode and the touch control signal line. The present embodiment is not limited thereto. In the present example, a common voltage signal is applied to a common electrode in a display phase to achieve a display function, and a touch control signal is applied to a common electrode in a touch control phase to achieve a touch control function. Therefore, there is no need to additionally manufacture a film layer in which a touch control electrode is located, so that a manufacturing process may be saved and a thickness of the array substrate may be reduced.

In some examples, as shown in FIGS. 15A and 15B, the first common voltage signal line 21 of the right bezel region B2 may have a plurality of first hollow portions 211. An orthographic projection of a first hollow portion 211 on the base substrate may be substantially in a shape of a rectangle, and the rectangle may have rounded corners or chamfers. The plurality of first hollow portions 211 may be aligned in the second direction Y. An orthographic projection of a first hollow portion 211 of the first common voltage signal line 21 on the base substrate may not be overlapped with an orthographic projection of the second common voltage signal line 22 on the base substrate.

In some examples, as shown in FIGS. 15A and 15B, the first common voltage signal line 21 of the right bezel region B2 may have a first edge close to the display area AA and a second edge away from the display area AA in the first direction X. The first edge may face a common electrode 15 of the display area AA, and the first edge may be substantially matched with a shape of an edge of an integral structure of the plurality of common electrodes 15 of the display area AA, for example, may substantially have a shape of a polyline extending along the second direction Y. The second edge of the first common voltage signal line 21 may have a plurality of notches 213. An orthographic projection of a notch 213 on the base substrate may be substantially rectangular. The plurality of notches 213 may be sequentially disposed along the second direction Y.

In some examples, as shown in FIGS. 6A to 15B, an orthographic projection of the first common voltage signal line 21 on the base substrate may cover an orthographic projection of the second common voltage signal line 22 on the base substrate. The first common voltage signal line 21 may be electrically connected with the second common voltage signal line 22 through a plurality of groups of first vias V1. For example, each group of first vias V1 may include two first vias V1 arranged along the first direction X. The plurality of groups of first vias V1 within the right bezel region B2 may be sequentially arranged along the second direction Y. The plurality of groups of first vias V1 and the plurality of first hollow portions 211 may be disposed at intervals in the second direction Y, thereby facilitating circuit layout.

In some examples, as shown in FIGS. 6A to15B, an orthographic projection of the first common voltage signal line 21 on the base substrate may cover an orthographic projection of a second dummy wire segment 252 of a dummy wire 25 on the base substrate. The second dummy wire segment 252 may be located at a side of a first hollow portion 211 close to the display area AA. A third dummy connection portion 2521 or a fourth dummy connection portion 2522 of the second dummy wire segment 252 may be electrically connected with the first common voltage signal line 21 through two sixth vias V6 arranged along the first direction X.

In some examples, as shown in FIG. 7A, a first opening for removing the third insulation layer 303 may be formed in a region where the third dummy connection portion 2521 (or the fourth dummy connection portion 2522) of the second dummy wire segment 252 is located, and the fourth insulation layer and the second insulation layer are etched away within the first opening to form two sixth vias V6, exposing the third dummy connection portion 2521 (or the fourth dummy connection portion 2522). The first common voltage signal line 21 may be electrically connected with the third dummy connection portion 2521 (or the fourth dummy connection portion 2522) through the first opening and the sixth vias V6. In this example, by etching a via after forming the first opening in the third insulation layer, it is possible to avoid insufficient contact of a conductive film layer due to an excessive depth of the via, and to ensure effectiveness of an electrical connection between the first common voltage signal line and the second dummy wire segment.

In some examples, as shown in FIGS. 6A to 15B, the first connection electrode 41 may be located at a side of the second common voltage signal line 22 close to the display area AA. The first connection electrode 41 may be electrically connected with a scanning connection end 111 of a scanning line 11 through two fourth vias V4 arranged along the second direction Y, and may also be electrically connected with the first end portion of the first connection line 232 through two fifth vias V5 arranged along the second direction Y. An orthographic projection of the first connection electrode 41 on the base substrate may be located within a range of an orthographic projection of a first hollow portion 211 of the first common voltage signal line 21 on the base substrate. For example, an orthographic projection of each first hollow portion 211 on the base substrate may cover an orthographic projection of one first connection electrode 41 on the base substrate. A plurality of first connection electrodes 41 within the right bezel region B2 may be sequentially disposed along the second direction Y. In this example, by disposing a first hollow portion on the first common voltage signal line to avoid a first connection electrode, effectiveness of an electrical connection of the first connection electrode to a scanning connection end of a scanning line and a first connection line may be ensured.

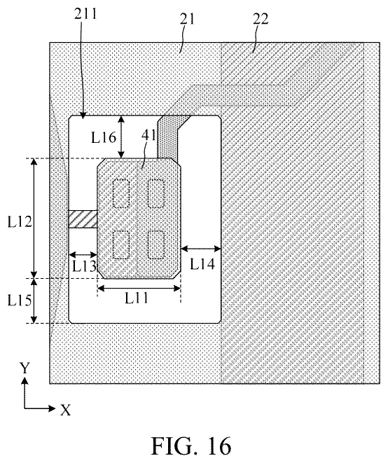

FIG. 16 is a schematic diagram of a partial region in FIG. 6A. In some examples, as shown in FIG. 16, an orthographic projection of a first connection electrode 41 on the base substrate may be substantially in a shape of a rectangle, for example, the rectangle may have rounded corners or chamfers. A length L11 of the first connection electrode 41 along the first direction X may be smaller than a length L12 along the second direction Y. For example, the length L11 of the first connection electrode 41 along the first direction X may be 25 microns (um) to 35 um, such as may be about 30 um; the length L12 of the first connection electrode 41 along the second direction Y may be 36 um to 45 um, for example, about 40 um.

In some examples, as shown in FIG. 16, in the first direction X, there is a first distance L13 between an edge of the first connection electrode 41 close to the display area AA and an edge of a first hollow portion 211 close to the display area AA, and there may be a second distance L14 between an edge of the first connection electrode 41 away from the display area AA and an edge of the first hollow portion 211 away from the display area AA. The second distance L14 may be greater than or equal to the first distance L13. For example, the first distance L13 and the second distance L14 may both be greater than 6 um, for example, the first distance L13 may be about 10 um and the second distance L14 may be about 15 um.

In some examples, as shown in FIG. 16, in the second direction Y, there is a third distance L15 between a lower edge of the first connection electrode 41 and an adjacent edge of the first hollow portion 211, and there is a fourth distance L16 between an upper edge of the first connection electrode 41 and an adjacent edge of the first hollow portion 211. The third distance L15 and the fourth distance L16 may be substantially the same. For example, the second distance L15 and the third distance L16 may both be about 15 um.

In some examples, as shown in FIGS. 6A to 15B, a second connection electrode 42 may be located at a side of the second common voltage signal line 22 away from the display area AA. An orthographic projection of the second connection electrode 42 on the base substrate may be substantially in a shape of a rectangle, for example, the rectangle may have chamfers or rounded corners. The second connection electrode 42 may be electrically connected with a second connection line 292 located in the second conductive layer through two seventh vias V7 arranged along the second direction Y, and may also be electrically connected with a first voltage line 23 located in the first conductive layer through two eighth vias V8. The two eighth vias V8 may be located on two sides of the two seventh vias V7 along the second direction Y. An orthographic projection of the second connection electrode 42 on the base substrate is at least partially overlapped with an orthographic projection of the first voltage line 23 on the base substrate; for example, the orthographic projection of the first voltage line 23 on the base substrate may cover the orthographic projection of the second connection electrode 42 on the base substrate.

In some examples, as shown in FIG. 15A, the orthographic projection of the second connection electrode 42 on the base substrate may be located within a range of an orthographic projection of a notch 213 on the base substrate. In the first direction X, the orthographic projection of the notch 213 on the base substrate may cover the orthographic projection of the second connection electrode 42 on the base substrate. An edge of the second connection electrode 42 away from the display area AA may be flush with a second edge of the first common voltage signal line 21 in the first direction X.

In some examples, as shown in FIG. 15A, in the first direction X, there may be a fifth distance L21 between an edge of the second connection electrode 42 close to the display area AA and a bottom surface of a notch 213; in the second direction Y, there may be a sixth distance L22 between a lower edge of the second connection electrode 42 and a side surface of the notch 213, and there may be a seventh distance L23 between an upper edge of the second connection electrode 42 and the side surface of the notch 213. The fifth distance L21, the sixth distance L22, and the seventh distance L23 may be greater than 6 um. For example, the fifth distance L21 may be about 8 um, the sixth distance L22 may be about 15 um, and the seventh distance L23 may be about 15 um. In this example, by disposing a first common voltage signal line to avoid a second connection electrode, effectiveness of an electrical connection of the second connection electrode to a first voltage line and a second connection line may be ensured.

In some examples, as shown in FIG. 7B, a second opening for removing the third insulation layer 303 may be formed in a region corresponding to a notch 213 of the first common voltage signal line 21, the fourth insulation layer and the second insulation layer are etched within the second opening to form two seventh vias V7, exposing a part of a surface of a second connection line 292 located in the second conductive layer, and the fourth insulation layer, the second insulation layer, and the first insulation layer are etched within the second opening to form two eighth vias V8, exposing a part of a surface of a first voltage line 23 located in the first conductive layer. The second connection electrode 42 may be electrically connected with the second connection line 292 through a seventh via V7, and may also be electrically connected with the first voltage line 23 through an eighth via V8. In this example, by etching a via after forming a second opening in the third insulation layer, it is possible to avoid insufficient contact of a conductive film layer due to an excessive depth of the via, and it is possible to ensure effectiveness of an electrical connection between a first voltage line and a second connection line.

In some examples, as shown in FIGS. 6A and 6B, in the right bezel region B2, a plurality of notches 213 of the first common voltage signal line 21 and extension ends 112 of a plurality of scanning lines 11 may be disposed at intervals in the second direction Y. Since second drive units of two adjacent stages may be electrically connected with a first voltage line 23 through a same second connection line and a second connection electrode, and the second connection electrode is located in a notch, the second drive units of two adjacent stages may share a second connection electrode in one notch to achieve an electrical connection with a first voltage line. By setting notches and extension ends of scanning lines at intervals in the second direction, circuit layout may be reasonably arranged, which is beneficial to saving space.

In some examples, the first insulation layer 301, the second insulation layer 302, and the fourth insulation layer 304 may be made of any one or more of Silicon Oxide (SiOx, x>0), Silicon Nitride (SiNy, y>0), and Silicon Oxynitride (SiON), and may be a single layer, a multi-layer, or a composite layer. The third insulation layer 303 may be made of an organic insulation material. The first conductive thin film and the second conductive thin film may be made of a metal material, such as any one or more of Argentum (Ag), Copper (Cu), Aluminum (Al), Titanium (Ti), and Molybdenum (Mo), or an alloy material of the aforementioned metals, such as an Aluminum-Neodymium alloy (AlNd) or a Molybdenum-Niobium alloy (MoNb), and may be of a single layer structure, or a multi-layer composite structure such as Ti/Al/Ti, etc. The first transparent conductive thin film and the second transparent conductive thin film may be made of a transparent conductive material such as indium tin oxide (ITO) or indium zinc oxide (IZO), etc. However, the present embodiment is not limited thereto.

The structure of the display substrate and the preparation process of the display substrate in the embodiment of the present disclosure are described only as an example. In some examples, a corresponding structure may be changed and a patterning process may be added or reduced according to actual needs. For example, a touch electrode may have a sheet-shaped electrode structure and does not have a slit, so that a touch control electrode has a larger area, which is beneficial to enhancing a touch control performance. However, the present embodiment is not limited thereto.

In the array substrate of the present example, by disposing a dummy wire to be disconnected at an extension end of a scanning line, it is possible to avoid intersection of the dummy wire with the extension end of the scanning line, thereby reducing a risk of a short circuit of the scanning line and the dummy wire caused by electrostatic discharge at the extension end of the scanning line, and further improving poor horizontal stripes-type functional display.

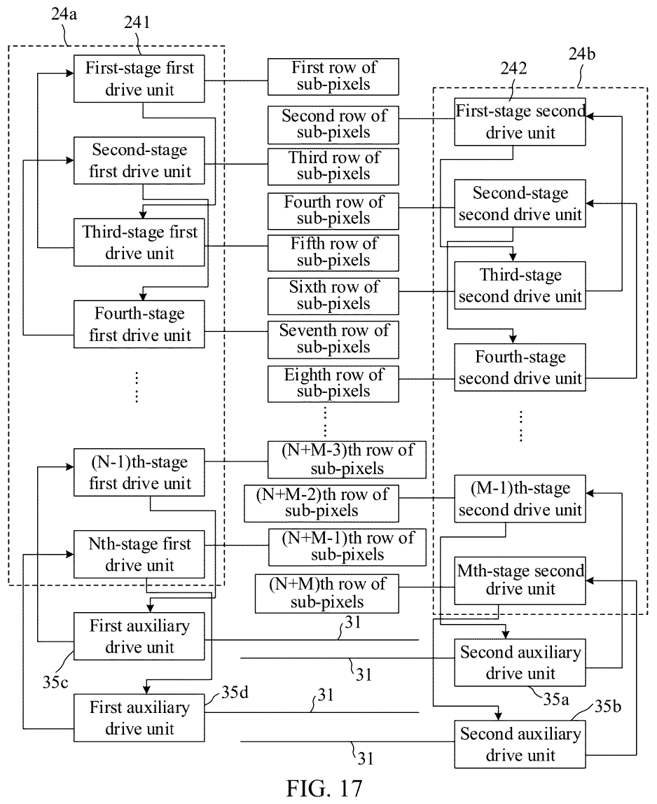

FIG. 17 is another schematic diagram of a scanning drive circuit according to at least one embodiment of the present disclosure. In some examples, as shown in FIG. 17, the array substrate may further include a plurality of auxiliary drive units (for example, including first auxiliary drive units 35c and 35d, and second auxiliary drive units 35a and 35b). Among them, the first auxiliary drive units 35c and 35d may be located in the left bezel region, and the second auxiliary drive units 35a and 35b may be located in the right bezel region.

In some examples, as shown in FIG. 17, the second auxiliary drive unit 35c located in the left bezel region may be cascaded with an (N−1)-th-stage first drive unit, and the second auxiliary drive unit 35d may be cascaded with an N-th-stage first drive unit. An output terminal of the N-th-stage first drive unit may be configured to provide an input signal to the first auxiliary drive unit 35d, and an output terminal of the first auxiliary drive unit 35d may be configured to provide a reset signal to the N-th-stage first drive unit; an output terminal of the (N−1)-th-stage first drive unit may be configured to provide an input signal to the first auxiliary drive unit 35c, and an output terminal of the first auxiliary drive unit 35c may be configured to provide a reset signal to the (N−1)-th-stage first drive unit. The second auxiliary drive unit 35a located in the right bezel region is cascaded with an (M−1)-th-stage second drive unit, and the second auxiliary drive unit 35b may be cascaded with an Mth-stage second drive unit. An output terminal of the (M−1)-th-stage second drive unit may be configured to provide an input signal to the second auxiliary drive unit 35a, and an output terminal of the second auxiliary drive unit 35a may be configured to provide a reset signal to the (M−1)-th-stage second drive unit; an output terminal of the M-th-stage second drive unit may be configured to provide an input signal to the second auxiliary drive unit 35b, and an output terminal of the second auxiliary drive unit 35b may be configured to provide a reset signal to the M-th-stage second drive unit.

In this example, by disposing a plurality of auxiliary drive units to provide reset signals to first drive units of last two stages and second drive units of last two stages, reset and drive effects of a first drive circuit and a second drive circuit may be guaranteed. However, the present embodiment is not limited thereto. In other examples, separate reset signals may be provided to first drive units of last two stages and second drive units of last two stages.

In some examples, a circuit structure of an auxiliary drive unit is similar to circuit structures of a first drive unit and a second drive unit. For example, the auxiliary drive unit may include at least a first auxiliary capacitor, a first electrode plate of the first auxiliary capacitor may be electrically connected with a pull-up node, and a second electrode plate may be electrically connected with an output terminal of the auxiliary drive unit.

In some examples, as shown in FIG. 17, the array substrate may further include a plurality of (e.g., four) auxiliary scanning lines 31 located at a lower bezel. The four auxiliary scanning lines 31 may be electrically connected with four auxiliary drive units in one-to-one correspondence. In this example, by disposing an auxiliary scanning line electrically connected with an auxiliary drive unit, it is possible to not only provide a release path for an output signal of the auxiliary drive unit, but also ensure process uniformity.

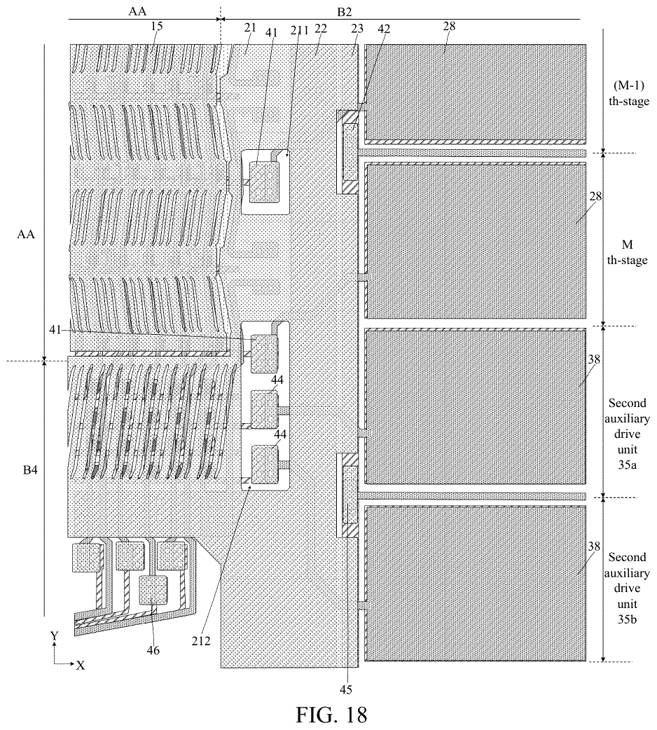

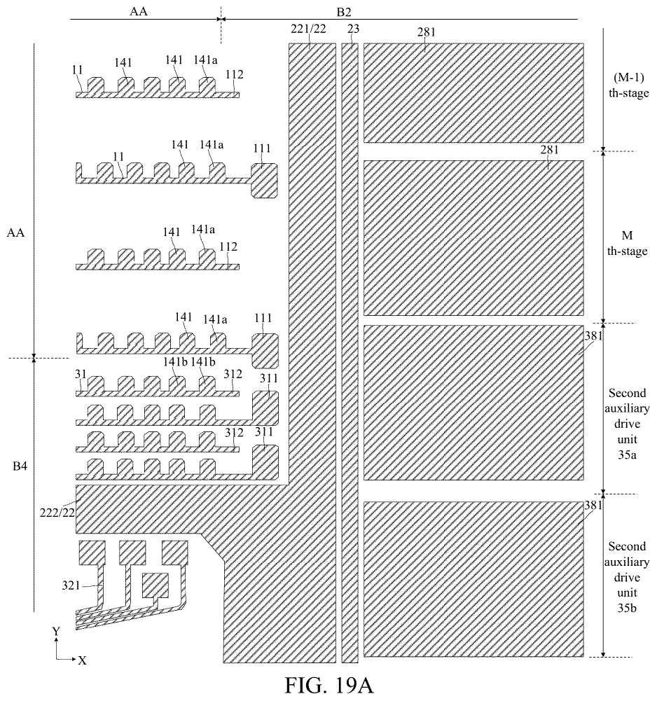

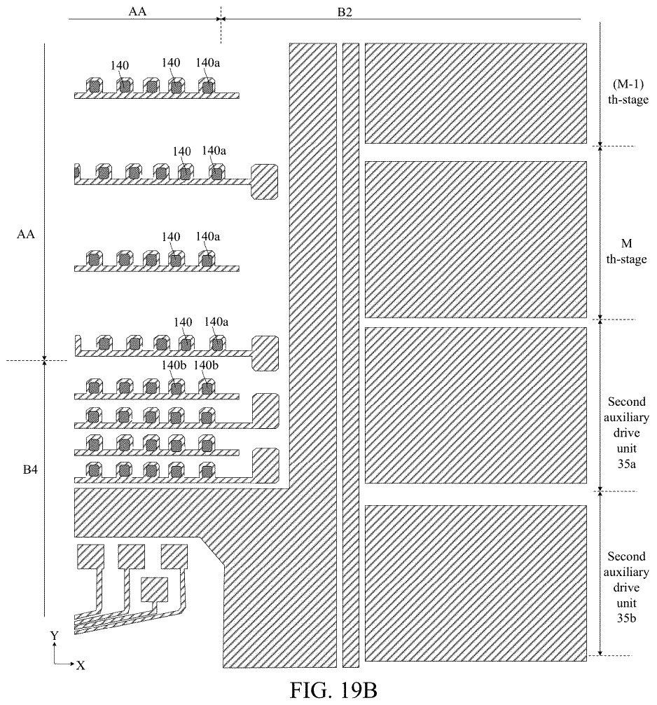

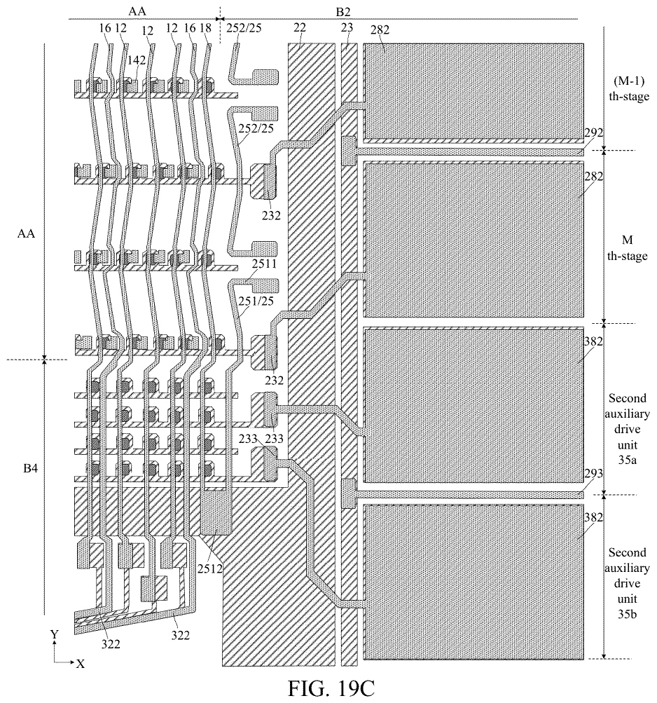

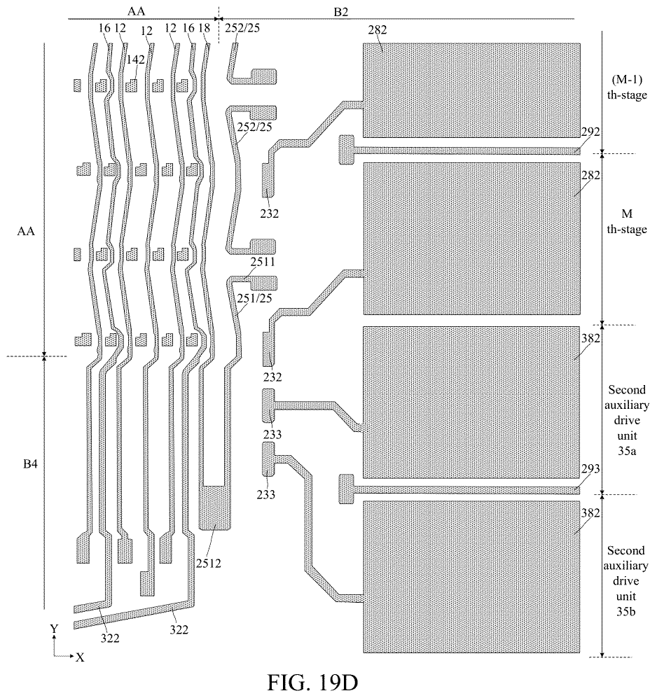

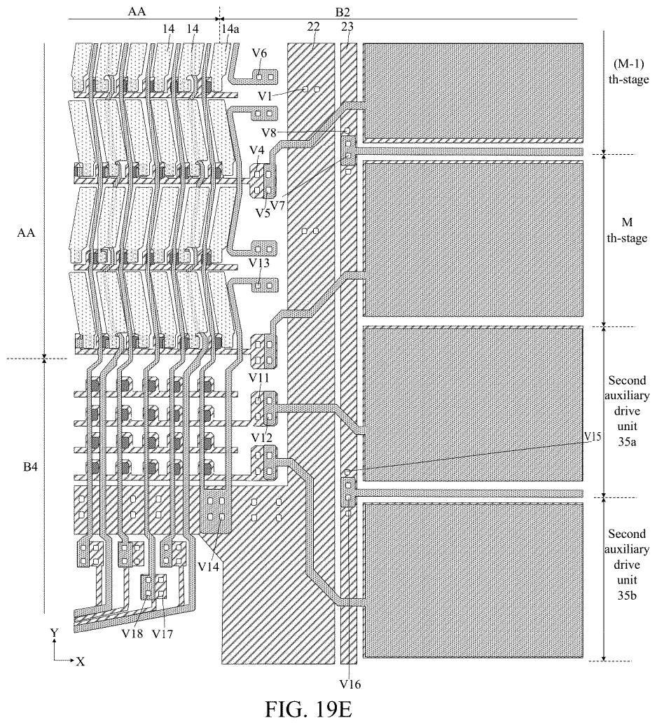

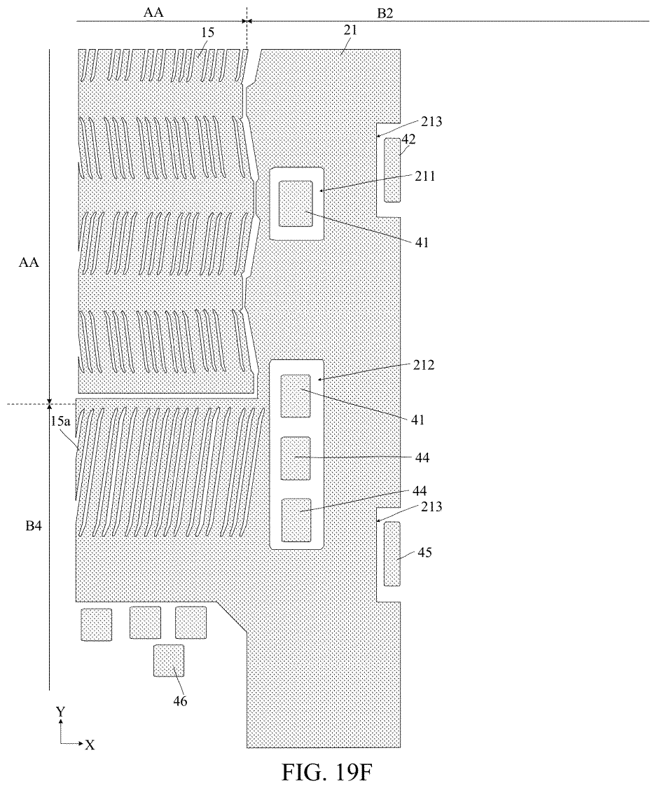

FIG. 18 is a schematic plan view of a lower right corner of an array substrate according to at least one embodiment of the present disclosure. FIG. 19A is a schematic diagram of the array substrate after a first conductive layer is formed in FIG. 18. FIG. 19B is a schematic diagram of the array substrate after a semiconductor layer is formed in FIG. 18. FIG. 19C is a schematic diagram of the array substrate after a second conductive layer is formed in FIG. 18. FIG. 19D is a schematic diagram of the second conductive layer in FIG. 19C. FIG. 19E is a schematic diagram of the array substrate after a fourth insulation layer is formed in FIG. 18. FIG. 19F is a schematic diagram of a second transparent conductive layer in FIG. 18.

In some examples, as shown in FIG. 19A, the first conductive layer may include at least first electrodes 381 of first auxiliary capacitors 38 of two second auxiliary drive units 35a and 35b located in the right bezel region B2, the second common voltage signal line 22 and the first voltage line 23, four auxiliary scanning lines 31 and a plurality of second dummy control blocks 141b located in the lower bezel region B4, and a plurality of data leading-out lines 321.

In some examples, as shown in FIG. 19A, the second common voltage signal line 22 may include a first signal segment 221 located within the right bezel region B2 and a second signal segment 222 located within the lower bezel region B4. The first signal segment 221 extends along the second direction Y, and the second signal segment 222 extends along the first direction X. The first signal segment 221 and the second signal segment 222 may be of an interconnected integral structure. For example, the first signal segment 221 may extend to the lower bezel region B4 and be electrically connected with an integrated chip.

In some examples, as shown in FIG. 19A, the first electrodes 381 of the first auxiliary capacitors of the two second auxiliary drive units 35a and 35b may be sequentially disposed along the second direction Y and arranged in alignment with a first electrode plate 281 of a first capacitor of the second drive unit in the second direction Y.

In some examples, as shown in FIG. 19A, the four auxiliary scanning lines 31 may be located at a side of the second signal segment 222 of the second common voltage signal line 22 close to the display area AA. Each auxiliary scanning line 31 may include an auxiliary scanning connection end 311 and an auxiliary extension end 312. In a lower right corner region, auxiliary extension ends 312 and auxiliary scanning connection ends 311 of the four auxiliary scanning lines 31 may be disposed at intervals along the second direction Y. Each auxiliary scanning line 31 may be electrically connected with a plurality of second dummy control blocks 141b arranged along the first direction X, for example, may be of an interconnected integral structure. By disposing the plurality of second dummy control blocks 141b, it is possible to make first conductive layer patterns of the display area AA and the lower bezel region B4 partially consistent, thereby ensuring process uniformity.

In some examples, as shown in FIG. 19A, the plurality of data leading-out lines 321 may be located at a side of the second signal segment 222 of the second common voltage signal line 22 away from the display area AA. The plurality of data leading-out lines 321 may extend to be electrically connected with the integrated chip.

In some examples, as shown in FIG. 19B, the semiconductor layer of the lower bezel region B4 may at least include a plurality of second dummy active blocks 140b. The plurality of second dummy active blocks 140b may be arranged in four rows and a plurality of columns. An orthographic projection of a second dummy active block 140b on the base substrate may be located within a range of an orthographic projection of a second dummy control block 141b on the base substrate. In this example, by disposing a plurality of second dummy active blocks 140b, process uniformity may be ensured.

In some examples, as shown in FIGS. 19C and 19D, a dummy wire 25 located in the right bezel region B2 may include a first dummy wire segment 251 and a second dummy wire segment 252. The first dummy wire segment 251 may include a first dummy connection portion 2511 and a second dummy connection portion 2512. The second dummy connection portion 2512 may extend to the lower bezel region B4, and an orthographic projection of the second dummy connection portion 2512 on the base substrate may be overlapped with an orthographic projection of the second signal segment 222 of the second common voltage signal line 22 on the base substrate. A shape and a connection mode of the first dummy connection portion 2511 are similar to those of the third dummy connection portion and the fourth dummy connection portion of the second dummy wire segment 252, description thereof will not be repeated here. The dummy data line 18 within the display area AA may extend to the lower bezel region B4 and be electrically connected with the second dummy connection portion 2512. For example, the dummy data line 18 and the second dummy connection portion 2512 may be of an interconnected integral structure. An orthographic projection of the first dummy wire segment 251 on the base substrate may be partially overlapped with orthographic projections of an auxiliary scanning connection end and an auxiliary extension end of an auxiliary scanning line on the base substrate. In this example, a dummy wire may not need to avoid an auxiliary scanning line.

In some examples, as shown in FIGS. 19C and 19D, the plurality of data lines 12 of the display area AA may extend to the lower bezel region B4. The plurality of touch control signal lines 16 may extend to the lower bezel region B4 and be electrically connected with a plurality of touch control leading-out lines 322 within the lower bezel region B4. For example, a touch control signal line 16 and a touch control leading-out line 322 may be of an interconnected integral structure.

In some examples, as shown in FIGS. 19C and 19D, an auxiliary scanning line may be electrically connected with an output terminal of a second auxiliary drive unit through a fourth connection line 233. A third connection line 293 may be disposed between the second auxiliary drive units 35a and 35b. The second auxiliary drive units 35a and 35b may share the third connection line 293 and be electrically connected with the first voltage line 23.

In some examples, as shown in FIG. 19E, the fourth insulation layer in the lower right corner region may be provided with a plurality of vias, and may include, for example, an eleventh via V11, a twelfth via V12, a thirteenth via V13, a fourteenth via V14, a fifteenth via V15, a sixteenth via V16, a seventeenth via V17, and an eighteenth via V18.

In some examples, the fourth insulation layer, the third insulation layer, the second insulation layer, and the first insulation layer within the eleventh via V11 may be removed, exposing a part of a surface of an auxiliary scanning connection 312 of an auxiliary scanning line. The fourth insulation layer, the third insulation layer, and the second insulation layer within the twelfth via V12 may be removed to expose a part of a surface of the fourth connection line 233. The fourth insulation layer, the third insulation layer, and the second insulation layer within the thirteenth via V13 may be removed to expose a part of a surface of the first dummy connection portion 2511 of the first dummy wire segment 251 of the dummy wire 25. The fourth insulation layer, the third insulation layer, and the second insulation layer within the fourteenth via V14 may be removed to expose a part of a surface of the second dummy connection portion 2512 of the first dummy wire segment 251 of the dummy wire 25. The fourth insulation layer, the third insulation layer, the second insulation layer, and the first insulation layer within the fifteenth via V15 may be removed to expose a part of a surface of the first voltage line 23. The fourth insulation layer, the third insulation layer, and the second insulation layer within the sixteenth via V16 may be removed to expose a part of a surface of the third connection line 293. The fourth insulation layer, the third insulation layer, the second insulation layer, and the first insulation layer within the seventeenth via V17 may be removed to expose a part of a surface of a data leading-out line 321. The fourth insulation layer, the third insulation layer, and the second insulation layer within the eighteenth via V18 may be removed to expose a part of a surface of a data line 12 extending to the lower bezel region B4.

In some examples, as shown in FIGS. 18 to 19F, the first common voltage signal line 21 may have a second hollow portion 212 at a lower right corner. The second hollow portion 212 may be aligned with the first hollow portion 211 in the second direction Y. The second hollow portion 212 may be located between an auxiliary drive unit and an auxiliary scanning line in the first direction X. An orthographic projection of the second hollow portion 212 on the base substrate may be substantially rectangular. The orthographic projection of the second hollow portion 212 on the base substrate may cover orthographic projections of three connection electrodes (including, for example, one first connection electrode 41 and two fourth connection electrodes 44) on the base substrate. The fourth connection electrode 44 may be electrically connected with an auxiliary scanning connection terminal 311 of an auxiliary scanning line through two eleventh vias V11 disposed vertically, and may also be electrically connected with the fourth connection line 233 through two twelfth vias V12 to achieve an electrical connection with an output terminal of a second auxiliary drive unit. The first connection electrode and the two fourth connection electrodes 44 within the second hollow portion 212 may be sequentially disposed along the second direction Y.

In some examples, as shown in FIGS. 18 to 19F, the first common voltage signal line 21 may be electrically connected with the first dummy connection portion 2511 of the first dummy wire segment 251 of the dummy wire 25 through two thirteenth vias V13. The first common voltage signal line 21 may be electrically connected with the second dummy connection portion 2512 of the first dummy wire segment 251 of the dummy wire 25 through four fourteenth vias V14 arranged in a 2×2 array.

In some examples, as shown in FIGS. 18 to 19F, a fifth connection electrode 45 located in the second transparent conductive layer may be electrically connected with the first voltage line 23 through two fifteenth vias V15, and may also be electrically connected with the third connection line 293 through two sixteenth vias V16. The fifth connection electrode 45 may be located in one notch of the first common voltage signal line 21 to achieve that the first common voltage signal line 21 avoids the fifth connection electrode 45 to ensure an effective electrical connection between an auxiliary drive unit and a first voltage line.

In some examples, as shown in FIGS. 18 to 19F, a sixth connection electrode 46 located in the second transparent conductive layer may be electrically connected with a data leading-out line 321 through two seventeenth vias V17, and may also be electrically connected with a data line 12 through two eighteenth vias V18, thereby achieving data signal transmission from the lower bezel region to the display area. A plurality of sixth connection electrodes 46 may be located at a side of the first common voltage signal line 21 away from the display area AA.

A structure of the lower left corner of the array substrate of the present example may be referred to a structure of the lower right corner, and rest of structures of the display area and the right bezel region of the array substrate of the present example may be referred to description of the foregoing embodiments, and therefore description will not be repeated here. Herein, an auxiliary scanning connection end, extending to the left bezel region, of an auxiliary scanning line may be electrically connected with a first auxiliary drive unit.

In the array substrate of the present example, by disposing an auxiliary drive unit and an auxiliary scanning line, reset and drive effects of a first drive circuit and a second drive circuit may be guaranteed, and process uniformity may be guaranteed.

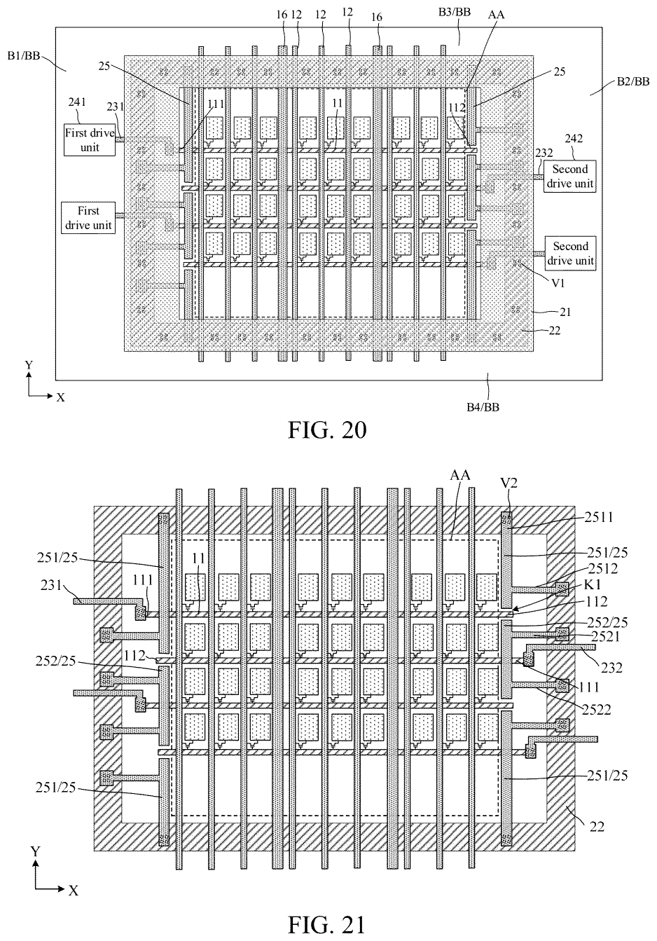

FIG. 20 is another schematic diagram of an array substrate according to at least one embodiment of the present disclosure. FIG. 21 is a schematic diagram of a partial film layer of FIG. 20. In some examples, as shown in FIGS. 20 and 21, a plurality of dummy wire segments (including a first dummy wire segment 251 and a second dummy wire segment 252) of dummy wires 25 located in the left bezel region B1 and the right bezel region B2 may all be electrically connected with the second common voltage signal line 22.

Rest of a structure of the array substrate of the present example may be referred to description of the aforementioned embodiments, and thus will not be repeated here.

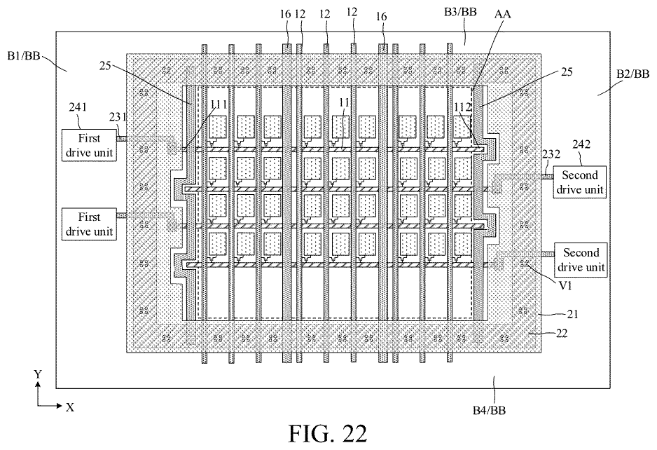

FIG. 22 is another schematic diagram of an array substrate according to at least one embodiment of the present disclosure. In some examples, as shown in FIG. 22, dummy wires 25 located in the left bezel region B1 and the right bezel region B2 may bypass an extension end 112 of a scanning line by bending, and orthographic projections of the dummy wires 25 and the extension end 112 of the scanning line on the base substrate may not be overlapped. In this example, it is possible to avoid intersection of a dummy wire with an extension end of a scanning line, thereby reducing a risk of a short circuit between the scanning line and the dummy wire caused by electrostatic discharge at the extension end of the scanning line, and further improving poor horizontal stripes-type functional display.

Rest of a structure of the array substrate of the present example may be referred to description of the aforementioned embodiments, and thus will not be repeated here.

In other examples, a disconnection design may be adopted for a dummy wire disposed in the left bezel region (or the right bezel region) of the array substrate to avoid an extension end of a scanning line, and a bypass design may be adopted for a dummy wire disposed in the right bezel region (or the left bezel region) to avoid an extension end of a scanning line. In other examples, a disconnection design and a bypass design may be simultaneously adopted for a dummy wire disposed in the left bezel region or the right bezel region of the array substrate to avoid extension ends of a plurality of scanning lines. The present embodiment is not limited thereto.

At least one embodiment of the present disclosure also provides a display apparatus, which includes the array substrate as described above.

In some examples, the display apparatus may include the array substrate, an opposite substrate, and a liquid crystal layer disposed between the array substrate and the opposite substrate. A pixel electrode and a common electrode (multiplexed as a touch control electrode) included in the array substrate are used for generating an electric field controlling deflection of liquid crystal molecules in the liquid crystal layer. In some examples, the opposite substrate may include an underlying substrate, and a black matrix and a color film disposed on the underlying substrate. However, the present embodiment is not limited thereto.

In some exemplary implementation modes, the display apparatus may be: any product or component with touch control and display functions such as a liquid crystal panel, electronic paper, a mobile phone, a tablet computer, a television, a display, a notebook computer, a digital photo frame, and a navigator.

The drawings of the present disclosure only involve structures involved in the present disclosure, and other structures may be referred to conventional designs. The embodiments of the present disclosure and features in the embodiments may be combined to each other to obtain new embodiments if there is no conflict. Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. An array substrate, comprising:
a base substrate comprising a display area and a bezel area located around the display area;
a plurality of scanning lines located at least in the display area and extending along a first direction;
at least one dummy wire located in the bezel area and extending along a second direction, wherein the second direction intersects with the first direction; and
a scanning drive circuit located in the bezel area;
wherein at least one scanning line of the plurality of scanning lines comprises: a scanning connection end and an extension end which extend to the bezel area, and the scanning connection end is electrically connected with the scanning drive circuit;
the at least one dummy wire is disconnected at the extension end of the at least one scanning line, to enable that an orthographic projection of the at least one dummy wire on the base substrate is not overlapped with an orthographic projection of the extension end of the at least one scanning line on the base substrate.

2. The array substrate according to claim 1, wherein the at least one dummy wire comprises a plurality of dummy wire segments sequentially arranged along the second direction, a first fracture is disposed between adjacent dummy wire segments in the second direction, and a length of the first fracture along the second direction is greater than a length of the extension end of the at least one scanning line along the second direction.

3. The array substrate according to claim 2, further comprising: a first common voltage signal line and a second common voltage signal line located in the bezel area; wherein the first common voltage signal line is electrically connected with the second common voltage signal line, the first common voltage signal line is located at a side of the second common voltage signal line away from the base substrate, and orthographic projections of the first common voltage signal line and the second common voltage signal line on the base substrate are at least partially overlapped.

4. The array substrate according to claim 3, wherein at least one dummy wire segment of the at least one dummy wire is electrically connected with at least one of the second common voltage signal line and the first common voltage signal line.

5. The array substrate according to claim 3, further comprising: a plurality of first connection lines located in the bezel area;
the scanning connection end of the at least one scanning line is electrically connected with the scanning drive circuit through a first connection line of the plurality of first connection lines; and the first connection line is located at a side of the scanning line away from the base substrate.

6. The array substrate according to claim 5, further comprising: a plurality of first connection electrodes located in the bezel area;
the scanning connection end of the scanning line is electrically connected with the first connection line through a first connection electrode of the plurality of first connection electrodes, and the first connection electrode is located at a side of the first connection line away from the base substrate.

7. The array substrate according to claim 6, wherein the first connection electrode and the first common voltage signal line are disposed in a same layer, the first common voltage signal line has a plurality of first hollow portions, and an orthographic projection of the first connection electrode on the base substrate is located within a first hollow portion of the plurality of first hollow portions.

8. The array substrate according to claim 3, further comprising: a first voltage line located in the bezel area and a plurality of second connection lines;
the first voltage line is located at a side of the first common voltage signal line and the second common voltage signal line away from the display area, and is located at a side of the scanning drive circuit close to the display area;
the first voltage line is electrically connected with the scanning drive circuit through a second connection line of the plurality of second connection lines, and the first voltage line is configured to provide a first voltage signal to the scanning drive circuit.

9. The array substrate according to claim 8, wherein the bezel area comprises at least: a left bezel region and a right bezel region located on two sides of the display area along the first direction;
the scanning drive circuit comprises a first drive circuit located in the left bezel region and a second drive circuit located in the right bezel region; the first drive circuit comprises a plurality of cascaded first drive units, and the second drive circuit comprises a plurality of cascaded second drive units;
in the left bezel region, a (2a−1)-th-stage first drive unit and a (2a)-th-stage first drive unit of the first drive circuit are electrically connected with the first voltage line through a same second connection line; and
in the right bezel region, a (2b−1)-th-stage second drive unit and a (2b)-th-stage second drive unit of the second drive circuit are electrically connected with the first voltage line through a same second connection line; where a and b are integers greater than 0.

10. The array substrate according to claim 8, further comprising: a plurality of second connection electrodes located in the bezel area, wherein the first voltage line is electrically connected with the second connection line through a second connection electrodes of the plurality of second connection electrodes; the second connection electrode is located at a side of the first voltage line and the second connection line away from the base substrate, and the second connection electrode and the first common voltage signal line are disposed in a same layer;
an edge of the first common voltage signal line away from the display area has a plurality of notches, at least one of the notches is configured to accommodate one of the second connection electrodes, and an orthographic projection of the at least one notch on the base substrate covers an orthographic projection of the second connection electrode on the base substrate in the first direction.

11. The array substrate according to claim 10, wherein the plurality of notches and extension ends of the plurality of scanning lines are disposed at intervals along the second direction.

12. The array substrate according to claim 1, wherein the bezel area comprises at least: a left bezel region and a right bezel region located at two sides of the display area along the first direction;
each of the left bezel region and the right bezel region is provided with at least one dummy wire.

13. The array substrate according to claim 1, wherein the bezel area comprises at least: a left bezel region and a right bezel region located at two sides of the display area along the first direction; and
in the left bezel region or the right bezel region, scanning connection ends and extension ends of the plurality of scanning lines are disposed at intervals along the second direction.

14. The array substrate according to claim 13, further comprising: a plurality of sub-pixels located in the display area, wherein the plurality of sub-pixels are arranged in a plurality of rows, and each row of sub-pixels comprises a plurality of sub-pixels arranged along the first direction;
the scanning drive circuit comprises a first drive circuit located in the left bezel region and a second drive circuit located in the right bezel region;
a scanning connection end of at least one scanning line extending to the left bezel region is electrically connected with the first drive circuit; the first drive circuit is configured to provide a data signal to a (2i−1)-th row of sub-pixels of the display area; and
a scanning connection end of at least one scanning line extending to the right bezel region is electrically connected with the second drive circuit; the second drive circuit is configured to provide a scanning signal to a (2i)-th row of sub-pixels of the display area; where i is an integer greater than 0.

15. The array substrate according to claim 14, wherein the bezel area further comprises a lower bezel region located at a side of the display area along the first direction;
the array substrate further comprises: a plurality of auxiliary scanning lines located in the lower bezel region and extending along the first direction, a plurality of first auxiliary drive units located in the left bezel region, and a plurality of second auxiliary drive units located in the right bezel region;
at least one of the plurality of auxiliary scanning lines comprises: an auxiliary scanning connection end extending to the left bezel region and an auxiliary extension end extending to the right bezel region; or, an auxiliary scanning connection end extending to the right bezel region and an auxiliary extension end extending to the left bezel region;
the auxiliary scanning connection end of the at least one auxiliary scanning line is electrically connected with a first auxiliary drive unit of the plurality of first auxiliary drive units or a second auxiliary drive unit of the plurality of second auxiliary drive units; and
in the left bezel region or the right bezel region, auxiliary scanning connection ends and auxiliary extension ends of the plurality of auxiliary scanning lines are disposed at intervals along the second direction.

16. The array substrate according to claim 15, wherein the plurality of first auxiliary drive units are configured to provide a reset signal to the first drive circuit; the plurality of second auxiliary drive units are configured to provide a reset signal to the second drive circuit.

17. The array substrate according to claim 1, wherein the at least one dummy wire bypasses an extension end of at least one scanning line from a side away from the display area.

18. A display apparatus, comprising the array substrate according to claim 1.

19. The array substrate according to claim 2, wherein the bezel area comprises at least: a left bezel region and a right bezel region located at two sides of the display area along the first direction;
each of the left bezel region and the right bezel region is provided with at least one dummy wire.

20. The array substrate according to claim 3, wherein the bezel area comprises at least: a left bezel region and a right bezel region located at two sides of the display area along the first direction;
each of the left bezel region and the right bezel region is provided with at least one dummy wire.
